(19) United States
(12) Patent Application Publication
(10) Pub. No.: US 2003/0091349 A1
(43) Pub. Date: May 15, 2003

(54) Optical data link

(76) Inventors: Shunsuke Sato, Yokohama-shi (JP); Toshio Mizue, Yokohama-shi (JP); Ichiro Tonai, Yokohama-shi (JP)

Correspondence Address: MCDERMOTT WILL & EMERY, 600 13TH STREET, N.W., WASHINGTON, DC, 20005-3096, US

(21) Appl. No.: 10/226,236

(22) Filed: Aug. 23, 2002

Related U.S. Application Data
(60) Provisional application No. 60/324,090, filed on Sep. 24, 2001.

(30) Foreign Application Priority Data
Aug. 23, 2001 (JP) P2001-253453

(51) Int. Cl. H01L 23/34; H05K 1/14

(52) U.S. Cl. 398/135; 361/736; 257/723; 361/748

(57) ABSTRACT

One aspect of the present invention is an optical data link. The optical data link comprises a housing, first and second optical communication subassemblies, first and second substrates, and electronic components. The housing has a base portion which extends along a reference plane. The first and second optical communication subassemblies are contained in the housing. The first and second substrates are contained in the housing. The electronic components are electrically connected with the first optical communication subassembly, and are mounted on the first substrate. The electronic components are also electrically connected with the second optical communication subassembly and are mounted on the second substrate. The first substrate is inclined at a first angle with respect to another reference plane orthogonal to the first reference plane.

### CROSS-REFERENCE TO RELATED APPLICATIONS

This application claims the benefit of the claiming priority of U.S. Provisional application Ser. No. 60/324,090, filed on Sep. 24, 2001, which provisional application is incorporated by reference herein.

### BACKGROUND OF THE INVENTION

1. Field of the Invention

The present invention relates to an optical data link.

2. Description of the Related Art

The optical data link comprises an optical receiver subassembly, an optical transmitter subassembly, an electronic component connected with the optical receiver subassembly, an electronic component connected with the optical transmitter subassembly, and a package that houses these subassemblies and electronic components. The optical receiver subassembly converts received light into electrical signals. These electrical signals are processed by an electronic component, and the processed electrical signals are then supplied to a lead terminal of the optical data link. The optical transmitter subassembly generates optical signals in response to drive signals, and the drive signals are generated by an electronic component that processes the electrical signals supplied via the lead terminals of the optical data link.

### SUMMARY OF THE INVENTION

There is one need for the miniaturization of an optical data link. In order to do this miniaturization, constituent components within a package must also be miniaturized. On the other hand, there is another need for an optical data link having their additional function. In order to provide the optical data link with this additional function, the package of the optical data link is required to house additional components. Therefore, the present inventors have identified the problems of finding a structure for an optical data link that satisfies these conflicting requirements.

Therefore, it is an object of the present invention to provide an optical data link that has a structure capable of increasing the area of a substrate on which electronic components in the optical data link are mounted.

One aspect of the present invention is an optical data link. This optical data link comprises a housing, first and second optical communication subassemblies, first and second substrates, an electronic component, and another electronic component. The housing has a base portion that extends along a reference plane. The first and second optical communication subassemblies are provided in the housing. The first and second substrates are provided in the housing. The electronic component is electrically connected with the first optical communication subassembly, and is mounted on the first substrate. Furthermore, the other electronic component is electrically connected with the second optical communication subassembly, and is mounted on the second substrate. The first substrate is provided so as to be inclined at a first angle with respect to another reference plane orthogonal to the first reference plane.

The first substrate maybe provided so as to be inclined at a certain angle with respect to the first reference plane, and may be provided so as to be inclined at the first angle with respect to the other reference plane orthogonal to the first reference plane.

In this optical data link, the second substrate is provided so as to be inclined at a certain angle with respect to the first reference plane and is provided so as to be inclined at a second angle with respect to another reference plane orthogonal to the first reference plane.

The second substrate may be provided so as to be inclined at a certain angle with respect to the first reference plane, and may be provided so as to be inclined at a second angle with respect to another reference plane orthogonal to the first reference plane.

The first substrate is preferably provided so as to be inclined at a first angle less than π/2 radian with respect to the other reference plane. The second substrate is provided so as to be inclined at a second angle less than π/2 radian with respect to the other reference plane.

Another aspect of the present invention relates to an optical data link. The optical data link comprises a first optical communication subassembly (e.g. optical receiver subassembly), a second optical communication subassembly (e.g. optical transmitter subassembly), a housing, a first substrate, a second substrate, an electronic component, and another electronic component. The optical receiver subassembly can receive light coming in a predetermined axial direction. The optical transmitter subassembly can transmit light in a predetermined axial direction. The housing has a base portion, and the base portion is provided along a first reference plane that extends in a direction from the optical receiver subassembly toward the optical transmitter subassembly. The optical receiver subassembly and the optical transmitter subassembly are provided in the housing. The first substrate is provided in the housing along a second reference plane inclined with respect to the first reference plane. The second substrate is provided in the housing along a third reference plane inclined with respect to the first reference plane. The electronic component is mounted on the first substrate, and is also electrically connected with the optical receiver subassembly. The other electronic component is mounted on the second substrate, and is electronically connected with the optical transmitter subassembly. The first and second substrates are provided along the second and third reference planes respectively, thereby increasing the area of the component mounting faces of the first and second substrates.

Yet another aspect of the present invention relates to an optical data link. The optical data link comprises a first substrate, a second substrate, a first optical communication subassembly (e.g. optical receiver subassembly), a second optical communication subassembly (e.g. optical transmitter subassembly), a housing, an electronic component, and another electronic component. The first substrate is provided so as to face a first side face of a reference triangle pole that extends in a predetermined axial direction, and the second substrate is provided so as to face a second side face of the reference triangle pole. The electronic component is mounted on the first substrate, and the other electronic component is mounted on the second substrate. The optical receiver subassembly is electrically connected with the first substrate, and the optical transmitter subassembly is electrically connected with the second substrate. The housing has a base portion, provided so as to face a third side face of the reference triangle pole, which mounts the first and second substrates, the optical receiver subassembly, and the optical transmitter subassembly thereon. The electronic and the other electronic components are provided in an electronic component disposing space provided between the first and second substrates.

Yet another aspect of the present invention relates to an optical data link. The optical data link comprises a housing, first and second substrates, an optical receiver subassembly, an optical transmitter subassembly, and electronic components. The housing includes abase portion extending along a reference plane and having first and second lead terminals thereon. The first lead terminal has a first portion that passes through the base portion, a second portion that is bent at a predetermined angle, excluding the π/2 radian, with respect to the first portion. The second lead terminal has a first portion that passes through the base portion, and a second portion that is bent at a prescribed angle, excluding the π/2 radian, with respect to the first portion.

Yet another aspect of the present invention relates to an optical data link. The optical data link comprises a housing, first and second substrates, an optical receiver subassembly, and an optical transmitter subassembly.

The housing includes a base portion and a wall portion. The base portion extends along a first reference plane. The wall portion extends on the base portion along a second reference plane intersecting the first reference plane. The wall portion has a first support face inclined at a first angle with respect to the first reference plane. The first support face of the wall portion supports the first substrate. The optical receiver subassembly is provided in the housing, and is electrically connected with the electronic component mounted on the first substrate. The wall portion also has a second support face inclined at a second angle with respect to the first reference plane. The second support face of the wall portion supports the second substrate. The optical transmitter subassembly is provided in the housing, and the optical transmitter subassembly is electrically connected with the electronic component mounted on the second substrate.

In the optical data link having the first support face and the second support face, the optical receiver subassembly has a plurality of lead terminals, and each lead terminal is curved to form an end portion. The curved end portions of these lead terminals extend in a direction represented by a first angle less than π/2 radian and greater than zero radian with respect to the reference plane. In this optical data link, the optical transmitter subassembly has a plurality of lead terminals, and each lead terminal is curved to form an end portion. The end portions of these lead terminals extend in a direction represented by a second angle less than π/2 and greater than zero radian with respect to the reference plane. The end portions of the lead terminals are bent in directions represented by the first and second angles respectively, thereby reducing the length of the lead terminals required for connecting with a corresponding substrate.

In the above mentioned optical data link, the base portion of the housing has first lead terminals connected with a first substrate, and second lead terminals connected with a second substrate. Each first lead terminal has a curved portion that is bent in a direction represented by an orientation of the end portions of the lead terminals of the optical receiver subassembly. Each second lead terminal has a curved portion that is bent in a direction represented by an orientation of the end portions of the lead terminals of the optical transmitter subassembly.

The orientation of the first lead terminals is matched with the orientation of the end portions of the lead terminals of the optical receiver subassembly. The orientation of the second lead terminals is matched with the direction of the end portions of the lead terminals of the optical transmitter subassembly. Therefore, this orientation serves to reduce the length of these lead terminals required to connect the respective substrates therewith. In the preferred embodiment, an angle formed by the curved end portions and the reference plane is not less than 10 degrees and not more than 80 degrees.

The optical receiver subassembly according to another aspect of the present invention relates to an optical data link. The optical data link comprises a housing, first and second substrates, an optical receiver subassembly, an optical transmitter subassembly, and electronic components. The housing includes a base portion which extends along a reference plane, and the first and second lead terminals are arranged on the base portion.

The optical receiver subassembly has a plurality of lead terminals, and each lead terminal has a bent end portion. The optical receiver subassembly is provided in the housing such that these end portions face a direction represented by an angle less than π/2 radian and greater than zero radian with respect to a reference plane. The lead terminals of the optical receiver subassembly are electrically connected with the first substrate within the housing, and the first substrate is inclined at an angle corresponding to the orientation of the lead terminals of the optical receiver subassembly. The electronic component is mounted on the first substrate.

The optical transmitter subassembly has a plurality of lead terminals, and each lead terminal has a curved end portion. The optical transmitter subassembly is provided in the housing such that these end portions faces a direction represented by an angle less than π/2 radian and greater than zero radian with respect to a reference plane. The lead terminals of the optical transmitter subassembly are electrically connected with the second substrate within the housing, and the second substrate is inclined at an angle corresponding to the orientation of the lead terminals of the optical transmitter subassembly. The electronic component is mounted on the second substrate.

In the preferred embodiment, the angle formed by the curved end portions and the reference plane is not less than 10 degrees and not more than 80 degrees.

The above objects and other objects, features and advantages of the present invention will become clear in the course of the detailed descriptions herein below of the preferred embodiments of the present invention with reference to the accompanied drawings.

### BRIEF DESCRIPTION OF THE DRAWINGS

FIG. 1 is a view showing the major parts of the optical data link according to a first embodiment;

FIGS. 2A and 2B are views each showing a photoelectric conversion device and a substrate;

FIG. 3 is a perspective view showing the optical data link according to the first embodiment;

FIG. 4 is a cross-sectional view corresponding to a view taken along the line I-I in FIG. 1;

FIGS. 5A and 5B show external views of the optical data link according to the first embodiment;

FIG. 6 is a cross-sectional view taken along the line II-II in FIG. 5B;

FIGS. 7A and 7B are views showing subassemblies;

FIG. 8 is a side view showing a connection between an optical connector and an optical data link;

FIGS. 9A and 9B are views each showing a substrate area according to the first embodiment;

FIGS. 10A and 10B are views showing a substrate area according to a comparative example;

FIGS. 11A and 11B are views each showing a substrate area according to still another comparative example;

FIG. 12 is a diagram showing the bit error rate characteristic of the optical data link;

FIG. 13 is a cross-sectional view of an optical data link according to a second embodiment;

FIG. 14 is a cross-sectional view of an optical data link according to a third embodiment;

FIG. 15 is a perspective view of the optical data link according to another embodiment;

FIG. 16 is a cross-sectional view taken along the line III-III in FIG. 15;

FIG. 17 is a views showing the optical data link according to an embodiment of the present invention;

FIGS. 18A and 18B are views each showing a photoelectric conversion device and a substrate in the optical data link;

FIGS. 19A to 19F are views showing the relationship between the circuit board and the photoelectric conversion device in various alignment positions with respect to the Z axis;

FIGS. 20A to 20F are views showing the arrangements of the photoelectric conversion device and the circuit board within the housing 3;

FIG. 21A is a view showing a substrate and a photoelectric conversion device which does not have an optical isolator;

FIG. 21B is a view showing a substrate and a photoelectric conversion device with an optical isolator;

FIG. 22A is a view showing a substrate and an optical data link comprising a photo electric conversion device which does not have an optical isolator;

FIG. 22B is a figure showing a substrate and an optical data link comprising a photoelectric conversion device with an optical isolator;

FIG. 23 is a perspective view showing an optical data link according to another embodiment;

FIG. 24 is a view showing a substrate, photoelectric conversion device, and heat transfer part;

FIG. 25A is a plan view showing the optical data link shown in FIG. 23A;

FIG. 25B is a plan view showing a modification of the optical data link shown in FIG. 23A;

FIG. 26A is a view showing a flex-rigid substrate and an optical data link comprising a photoelectric conversion device with three lead terminals T₁ to T₃;

FIG. 26B is a view showing a flex-rigid substrate and an optical data link comprising a photoelectric conversion device with four lead terminals T₄ to T₇;

FIG. 27 is a graph showing the noise margin of the optical data links shown in FIG. 26A and FIG. 26B; and

FIG. 28 is a view showing an optical data link according to a modification applicable to the embodiments described heretofore.

### DETAIL DESCRIPTION OF THE PREFERRED EMBODIMENTS

The teachings of the present invention can be easily understood with reference to the accompanied drawings illustrated by way of example through consideration of the detailed description herein below. The optical data link of the present embodiment will now be described referring to the accompanied drawings. Where possible, like parts are referred to as like reference numerals.

(First embodiment)

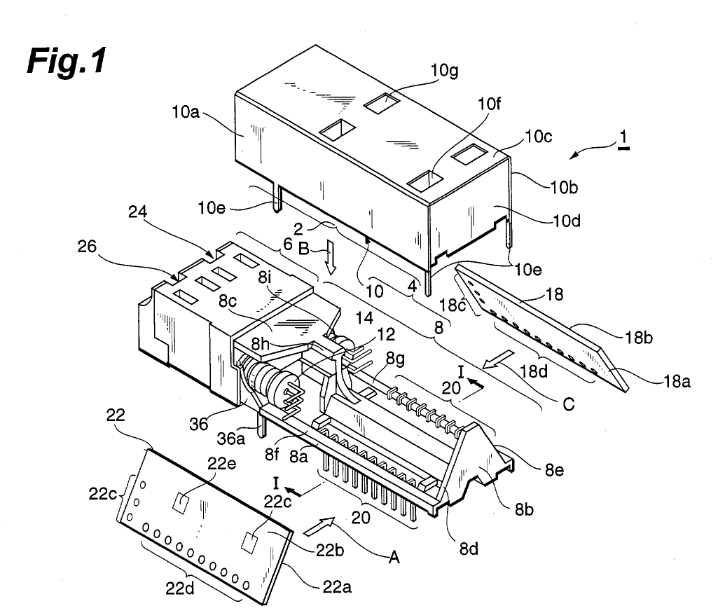

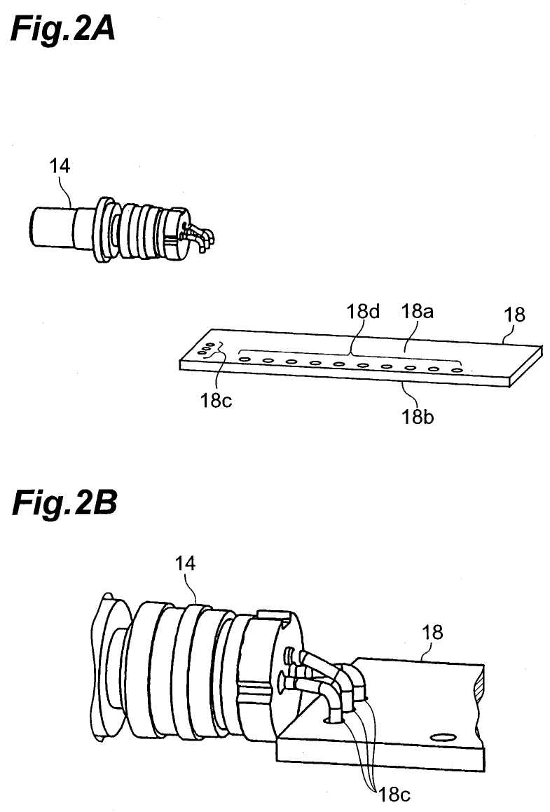

FIG. 1 shows an optical communication module according to the embodiments of the present invention. FIG. 2 shows a photoelectric conversion device and a substrate in the optical communication module. An optical data link is an example of the optical communication module. An optical communication subassembly is an example of the photoelectric conversion device.

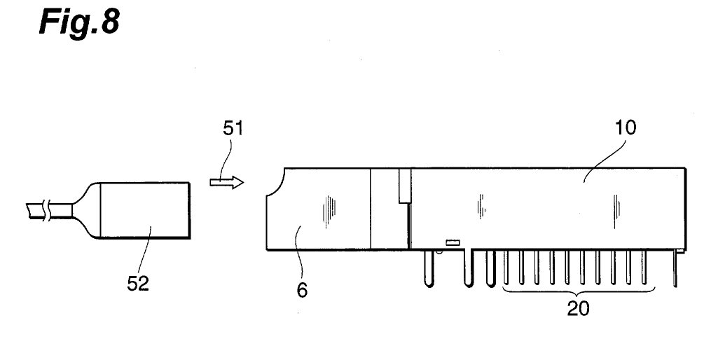

The optical communication module 1 comprises a housing 2, a first photoelectric conversion device 12, and a second photoelectric conversion device 14. The housing 2 can have a housing member 4, and a receptacle member 6. The first and second photoelectric conversion device 12 and 14 are supported by the housing member 4. Receptacles 24 and 26 are provided with the receptacle member 6 and extend in a prescribed axial direction. The receptacles 24 and 26 are provided so as to house optical connectors (reference numeral 52 in FIG. 8, for example). The housing member 4 has a mounting member 8 and a cover member 10. The mounting member 8 has substrates 18 and 22 for the photoelectric conversion devices 12 and 14 mounted thereon. The cover member 10 is placed on the mounting member 8 such that the photoelectric conversion devices 12 and 14 and the substrates 18 and 22 is located between the mounting member 8 and the cover member 10.

The housing 2 includes the receptacle member 6, the mounting member 8, and the cover member 10. The housing 2 provides a housing space in which the photoelectric conversion devices 12 and 14 are provided so as to be optically coupling to optical connectors (reference numeral 52 in FIG. 8).

The receptacle member 6 has a bottom portion with guide holes that extend along a prescribed axial direction to reach the receptacles 24 and 26. These guide holes guide the photoelectric conversion devices 12 and 14 such that the heads thereof protrude at the respective receptacles 24 and 26 with alignment with a prescribed axis. The receptacle member 6 has a wall portion provided between the heads of the photoelectric conversion devices 12 and 14 inserted into the respective guide holes. The wall portion serves to form an electrical shield between the photoelectric conversion devices 12 and 14.

The mounting member 8 has a base portion 8a, a rear wall portion 8b, and a ceiling portion 8c. The base portion 8a extends along a prescribed reference plane. The rear wall portion 8b is provided on one edge of the base portion 8a and extends in a direction intersecting the reference plane, and also extends in a direction intersecting the optical axis of the photoelectric conversion devices 12 and 14. The ceiling portion 8c extends in a direction in which the reference plane extends, and is provided in a position spaced apart from the wall portion 8b. The photoelectric conversion devices 12 and 14 are disposed between the base portion 8a and the ceiling portion 8c.

The base portion 8a has a series of lead terminals 20 and these lead terminals 20 permit an electrical connection of the photoelectric conversion devices 12 and 14 with external parts. The lead terminals 20 are provided on the bottom face of the base portion 8a that is to face a mounting substrate (not shown), and the lead terminals 20 are bent at a predetermined position away from the mounting face of the base portion. In this embodiment, the lead terminals 20 are arranged in a pair of rows in a direction in which the wiring substrates 18 and 22 extend. The lead terminals 20 are arranged in a prescribed axial direction.

It is preferable that at least apart of the receptacle member 6 has electrical conductivity. The material used for the receptacle member 6 and mounting member 8 preferably includes a synthetic resin material, such as a liquid crystal polymer. With this material, it is easy to form complicated shapes of the above members. In order to permit electrical shielding, the surface of the receptacle member 6 is preferably covered by an electrically conductive film, such as a plating film. The receptacle member 6 is mated to the mounting member 8 to secure the receptacle member 6 and the mounting member 8 to each other.

A terminal member 36 is provided so as to make contact with the bottom portion of the receptacles 24 and 26. The terminal member 36 can be utilized for connecting the receptacle member 6 with the reference potential line of the mounting substrates. To make this connection, the terminal member 36 comprises one or more connection terminals 36a, known as stud pins, that extend in the same direction as the terminal pins 20. In the terminal member 36 having a plurality of connection terminals 36a, the terminal member 36 has a bridging portion connecting a pair of terminals 36a across the bottom face of the receptacle member 6. This bridging portion is housed in a recess provided on the bottom face of the receptacle member 6. The terminal member 36 is positioned at the border of the guide holes and in the recess, and is mated to this recess provided at the border of the guide holes 30 so that the receptacle member 6 holds it.

The first and second photoelectric conversion device 12 and 14 are both capable of converting one of light signals and electrical signals to the other. The first and second photoelectric conversion device 12 and 14 have optical communication subassemblies. The optical communication subassemblies are provided as an optical receiver subassembly that converts light signals into electrical signals, and an optical transmitter subassembly that converts electrical signals into light signals. The optical receiver subassembly comprises an opto-electric conversion element portion including a semiconductor light receiving element, a housing that houses this opto-electric conversion element portion, and lead terminals provided in this housing. The optical transmitter subassembly comprises an electro-optic conversion element portion including a semiconductor light emitting element, a housing that houses this electro-optic conversion element portion, and lead terminals provided in this housing.

The wire substrates 18 and 22 comprise the component mounting faces 18a and 22a and opposite faces 18b and 22b, respectively. The component mounting face 18a and the opposite face 18b extend in a direction in which a prescribed reference plane extends. The component mounting face 22a and opposite face 22b extend in a direction in which another reference plane extends. The prescribed reference plane intersects with the other reference plane. In a preferred embodiment, the angle formed by the predetermined reference plane and the other reference plane is not less than 20 degrees and not more than 160 degrees. Wiring layers to enable an electrical connection between mounted components are provided on the component mounting faces 18a and 22a. Various electronic components or electronic elements are mounted on the component mounting faces 18a and 22a, and these electronic components or electronic elements are connected via the wiring layers. Furthermore, opposite faces 18b and 22b may also be constituted such that the electronic components or elements are mounted thereon. The opposite faces 18b and 22b may also be provided with respective electrically conductive layers, each of which is provided substantially over the entire surface thereof. This electrically conductive layer is preferably connected to a reference potential line.

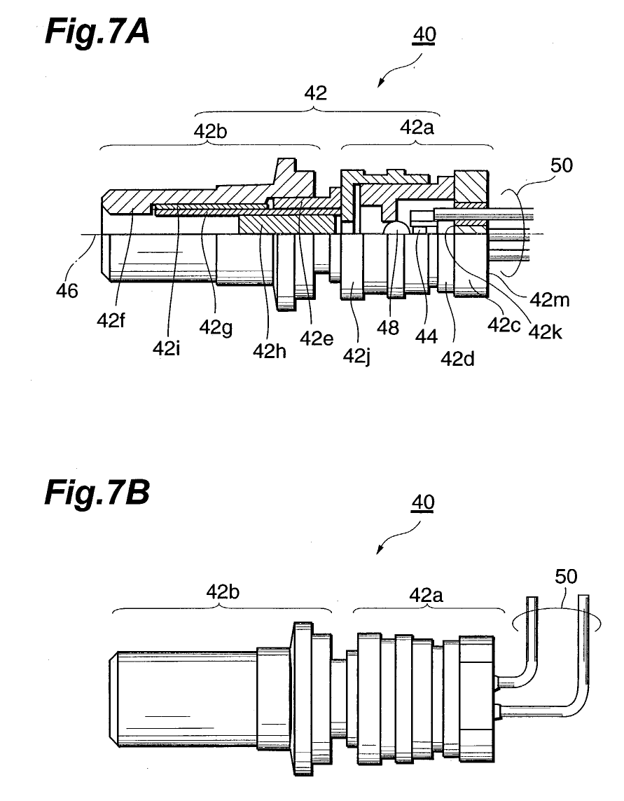

The wiring substrate 18 has first holes 18c and second holes 18d. Connection pins (reference numeral 50 in FIGS. 7A and 7B) of the opto-electric conversion element or electro-optic conversion element are inserted into the first holes 18c. The lead terminals 20, provided on the housing member, are inserted into the second holes 18d. The wiring substrate 22 has first holes 22c and second holes 22d. Connection pins of the opto-electric conversion element or an electric-optic conversion element (reference numeral 50 in FIGS. 7A and 7B) are inserted into the first holes 22c. The lead terminals 20, provided on the housing member, are inserted into the second holes 22d. The first holes 18c and 22c and the second holes 18d and 22d pass through from the component mounting faces to the respective opposite face thereof. The first holes 18c and 22c are arranged around the respective edges of the wiring substrates 18 and 22. The second holes 18d and 22d are arranged along the respective edges of the wiring substrates that extend in a predetermined axial direction.

The wiring substrates 18 and 22 are disposed such that each of the component mounting faces 18a and 22a face the other. Consequently, a space is created between the wiring substrates 18 and 22. The wiring substrates 18 and 22 are disposed so as to be inclined with respect to the reference plane along which the base portion 8a extends, but the wiring substrates 18 and 22 are not disposed in parallel. In order to define this angle of inclination, the mounting member 8 has support faces 8d and 8e on lateral edges of the wall portion 8b, has support faces 8f and 8g along respective edges of the base portion 8a, and has support faces (guide faces) 8h and 8i on a pair of edges of the ceiling portion 8c. The support faces 8d and 8e are provided so as to support upper lateral edges of the wiring substrates 18 and 22, respectively. The support faces 8f and 8g are provided so as to support lower edges of the wiring substrates 18 and 22, respectively. The support faces 8h and 8i are provided so as to support upper edges of the wiring substrates 18 and 22, respectively. These support faces function as guide faces. These guide faces serve to prevent the wiring substrates 18 and 22 from moving to an unexpected position in mounting the wiring substrates 18 and 22 in the housing. The guide faces also serve to prevent the first substrate from being disposed at an unexpected position within the housing.

Together with the mounting member 8, the cover member 10 provides a space for accommodating the first and second photoelectric conversion devices 12 and 14. The cover member 10 is preferably made of an electrically conductive material. To obtain the cover member 10, the cover member 10 may be made of metal or may comprises an electrically conductor on at least the surface thereof. The cover member 10 thus serves to electrically shield the first and second photoelectric conversion devices 12 and 14 and the wiring substrates 18 and 22.

The cover member 10 comprises side portions 10a and 10b, a lid portion 10c, and a rear portion 10d. The wiring substrates 18 and 22 are provided between the side portions 10a and 10b. The lid portion 10c faces the base portion 8a, and the side portions 10a and 10b are provided on both opposite edges of the lid portion 10c. The rear portion 10d is adjacent to the side portions 10a and 10b and the lid portion 10c, and intersects a predetermined axis in a direction of which the receptacles 24 and 26 extend. The cover member 10 can comprise a connecting terminal 10e provided in at least one of the side portions 10a and 10b and rear face portion 10d. This connecting terminal 10e is provided so as to be connected with a reference potential line of a mounting substrate in mounting this optical communication module 1 on the mounting substrate. Therefore, a reference potential line is supplied to the cover member 10, so that the electrical shield can be reliably provided.

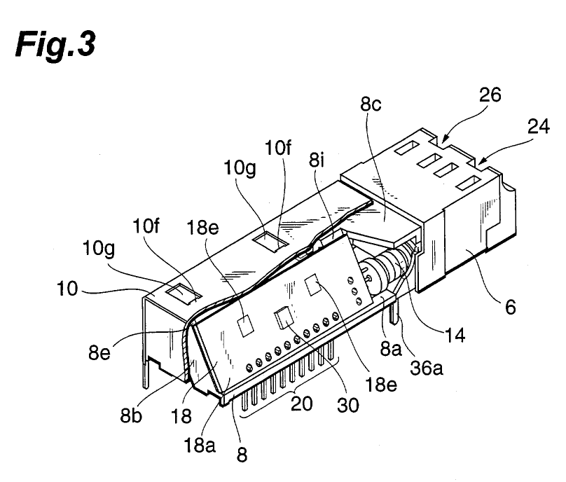

One or more fingers 10f are provided on the lid portion 10c. The fingers 10f are curved into the inside of the housing from the lid portion 10c. Because of the bending of the fingers, openings 10 g are formed in the lid portion 10c. The fingers 10f are curved from the lid portion 10c and thus make contact with opposite faces 18b and 22b of the wiring substrates 18 and 22. This contact permits the transferring of heat generated in the wiring substrates 18 and 22 to the cover member 10. In order to make this contact, a pad metal layer 22e is provided on the wiring substrate 22, and a pad metal layer (18e in FIG. 3) is provided on the wiring substrate 18. The cover member 10 radiates this heat in the air via the surface of the cover member 10. That is, the cover member 10 also functions as a heat sink.

The wiring substrates 18 and 22 can also comprise a thermal via formed from metal within abase insulation layer thereof. This thermal via is preferably provided in a mounting position of an electronic component, and makes the thermal radiation efficient by means of the connection thereof with another electrically conductive layer. A thermal via is connected with the pad metal layer 22e, but is electrically isolated from electronic components. In FIG. 1, the wiring substrate 22 is moved in the direction indicated by Arrow A, and then attached to the mounting member 8. The wiring substrate 18 is moved in the direction indicated by Arrow C, and is then attached to the mounting member 8, and the cover member 10 is moved in the direction indicated by Arrow B, and is then attached to the mounting member 8. A finished optical data link 1 is thus obtained.

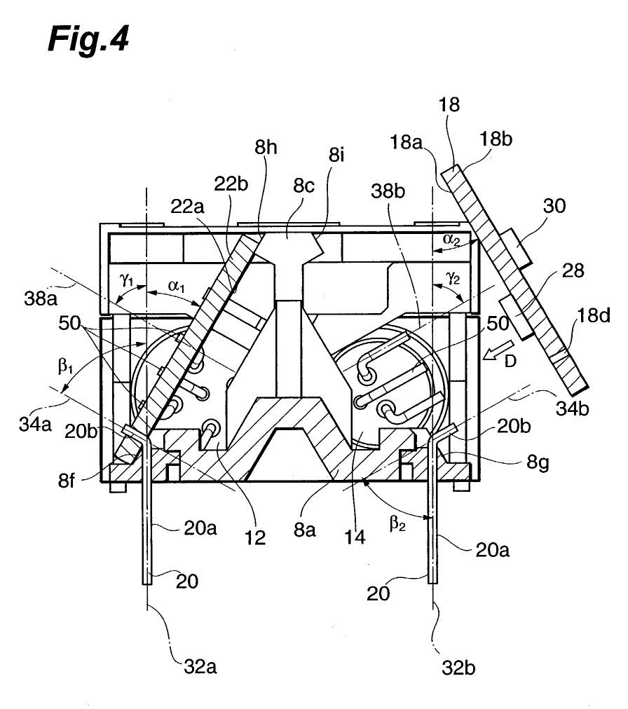

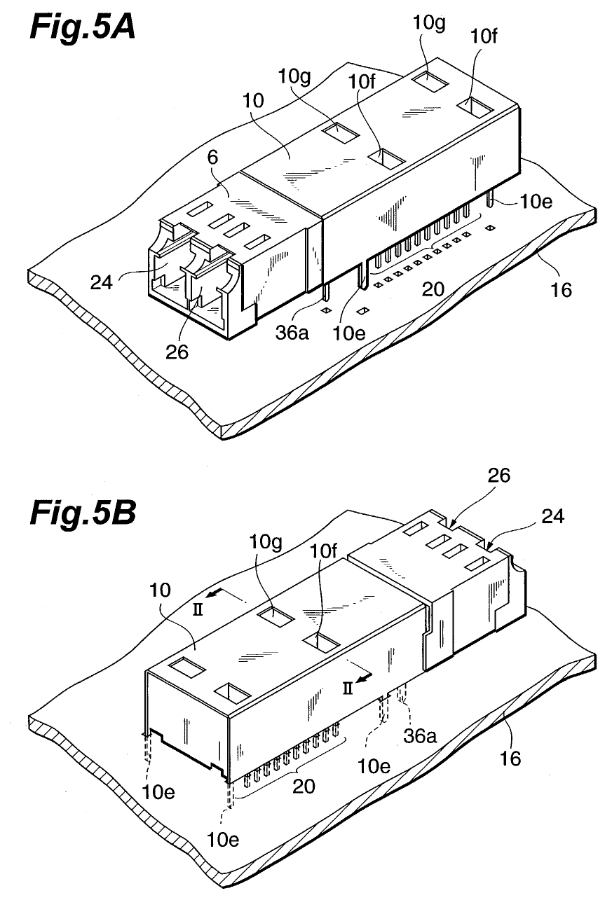

FIG. 3 is a perspective view showing an optical data link 1 obtained by assembling the parts shown in FIG. 1. In order to illustrate the interior of the optical data link 1, a part of the cover member 10 has been cut away. FIG. 4 shows a cross-sectional view taken along the line I-I in FIG. 1. In FIG. 4, the substrate 18 is shown under a separate condition in order to illustrate the direction of the attachment of the wiring substrate. FIG. 5A shows a perspective view of the optical data link 1 seen from the front thereof, and FIG. 5B shows a perspective view of the optical data link 1 seen from the rear thereof. FIG. 5A further illustrates a substrate 16 on which the optical data link 1 is to be disposed. In FIG. 5B, the optical data link 1 is mounted on the substrate 16.

In FIG. 3, the wiring substrates 18 and 22 are disposed so as to be inclined with respect to a reference plane along which the base portion 8a extends. In one preferred embodiment, the angle formed by the wiring substrate 18 and the reference plane is not less than 10 degrees and not more than 80 degrees. The angle formed by the wiring substrate 22 and the reference plane is not less than 10 degrees and not more than 80 degrees.

Referring to FIG. 4, the wiring substrate 22 is disposed so as to be inclined at an angle α₁ with respect to another reference plane indicated by the dashed line 32a orthogonal to the reference plane. In order to make this angle of inclination, the component mounting face 22a of the wiring substrate 22 faces the support faces 8f and 8h, so that the support faces 8f and 8h support the wiring substrate 22. In addition, the support face 8d may also support the wiring substrate 22, or the support face 8f and support face 8d (see FIG. 1) or the support face 8d and support 8h may support the wiring substrate 22. The angle α₁ may be greater than zero radian and smaller than π/2 radian. As for the wiring substrate 22, each of the lead terminals 20 has a first portion 20a extending along another reference plane indicated by the dashed line 32a, and a second portion 20b inclined at an angle β₁ (radian) with respect to another reference plane indicated by the dashed line 32a. The second portion 20b of each lead terminal 20 is inserted in a hole 22d of the wiring substrate 22. In order to make this insertion easier, the angle β₁ is formed to be substantially equal to an angle π/2−α₁ (radian). The first photoelectric conversion device 12 is oriented at an angle γ₁ (radian) such that the lead terminals 50 face the direction of another reference plane indicated by the dashed line 38a. The lead terminals 50 of the first photoelectric conversion device 12 are inserted into holes 22c in the wiring substrate 22. In order to make this insertion easier, the angle is γ₁ is formed to be substantially equal to the angle β₁.

Referring to FIG. 4, the lead terminals 50 of the second photoelectric conversion device 14 are oriented at an angle γ₂ (radian) in a direction with respect to another reference plane indicated by the dashed line 38b. The lead terminals 20b are oriented at an angle β₂ (radian) in the direction with respect to another reference plane indicated by the dashed line 34b. When the wiring substrate 18 is moved in the direction of Arrow D, the lead terminals 50 and the lead terminals 20b of the second photoelectric conversion device 14 are inserted into the holes 18c and holes 18d, respectively. The component mounting face 18a of the wiring substrate 18 makes contact with the support faces 8g and 8i, and the wiring substrate 18 is positioned at an angle β₂ (radian) by the support faces 8g and 8i. Furthermore, the wiring substrate 18 may be supported by the support face 8e. The wiring substrate 18 may be supported by the support faces 8g and 8e (see FIG. 1) or by the support faces 8e and 8i. The angle α₂ maybe greater than zero radian and smaller than π/2 radian. The angle β₂ is formed to be substantially equal to an angle π/2−α₂ (radian). The angle γ₂ is formed to be substantially equal to the angle β₂.

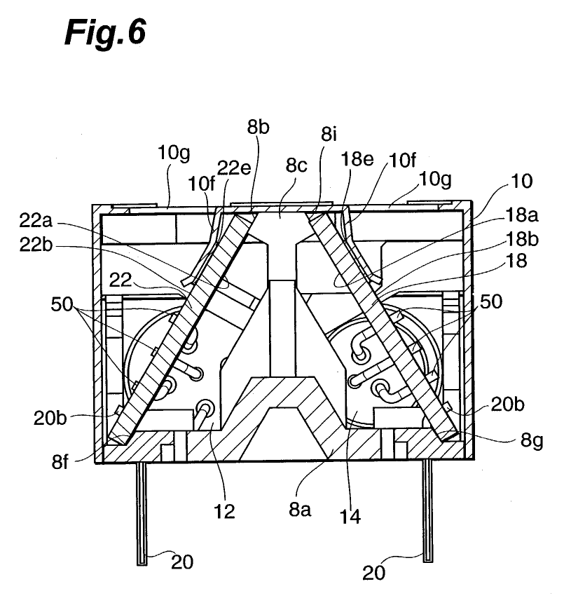

FIG. 6 is a cross-sectional view taken along the line II-II in FIG. 5B. FIG. 6 shows a configuration that the fingers 10f of the cover member 10 makes contact with the wiring substrate 18 and that the fingers 10f of the cover member 10 makes contact with the wiring substrate 22. The component mounting face 18a of the wiring substrate 18 is in contact with the support faces 8g and 8i of the mounting member 8, and the opposite face 18b is in contact with the fingers 10f. Similarly, the component mounting face 22a of the wiring substrate 22 is in contact with the support faces 8f and 8h of the mounting member 8, and the opposite face 22b is in contact with the fingers 10f.

FIG. 7A and FIG. 7B illustrate a semiconductor optical element 44, such as an opto-electric conversion element and electro-optic conversion element included in the first and second photoelectric conversion device 12 and 14. The opto-electric conversion element is, for example, a semiconductor light receiving element, such as a photo-diode (pin photo-diode, avalanche photo-diode). The electro-optic conversion element is, for example, a semiconductor light emitting element, such as a light emitting diode or semiconductor laser.

The semiconductor optical element 44, such as the opto-electric conversion element and electro-optic conversion element, can be housed in a container 42, such as a package. The container 42 has an element housing portion 42a and a guide portion 42b.

In an element housing portion 42a of the container 42, the opto-electric conversion element or electro-optic conversion element 44 are hermetically sealed. The element housing portion 42a has a base 42c, such as a stem, made of a metallic material, such as copper. The base 42c can be used as an element mounting member that has an element face 42k to mount the semiconductor optical element, and an opposite face 42m opposed to the element face 42k of the base 42c. A lens cap 42d made of a metallic material, such as stainless, is mounted on the base 42c. The lens cap 42d is used as a lens holding member. The element housing portion 42a is provided with a window portion secured to the lens cap 42d. The window portion 48 is capable of transmitting light associated with the opto-electric conversion element or electro-optic conversion element 44, and may also comprise a condensing lens 48. The lens cap 42d is placed inside a holder 42j made of a metallic material, such as stainless steel. The base 42c may also have connecting pins 50 for the electrical connection of the semiconductor optical element 44, such as the opto-electric conversion element or electro-optic conversion element. The container 42 is secured to the corresponding wiring substrate 18 or 22 by means of the connecting pins 50. The connecting pins 50 are curved such that the optical axis 46 of the element 44 follows an axis of the receptacle.

A guide portion 42b has a guide member 42e made of a metallic material, such as stainless steel. The guide member 42e is secured on a holder 42j. A sleeve 42f made of a metallic material, such as stainless steel, is provided on the outside of the guide member 42e. A split sleeve 42g made of material, such as zirconia, is contained in the guide member 42e. The split sleeve 42g positions as tub 42h holding an optical fiber. The split sleeve 42g is secured to the sleeve 42f by a securing member 42i.

FIG. 8 is a side view of the optical communication module 1 according to the present embodiment. An optical connector 52 is inserted into the optical communication module 1 in the direction of arrow 51.

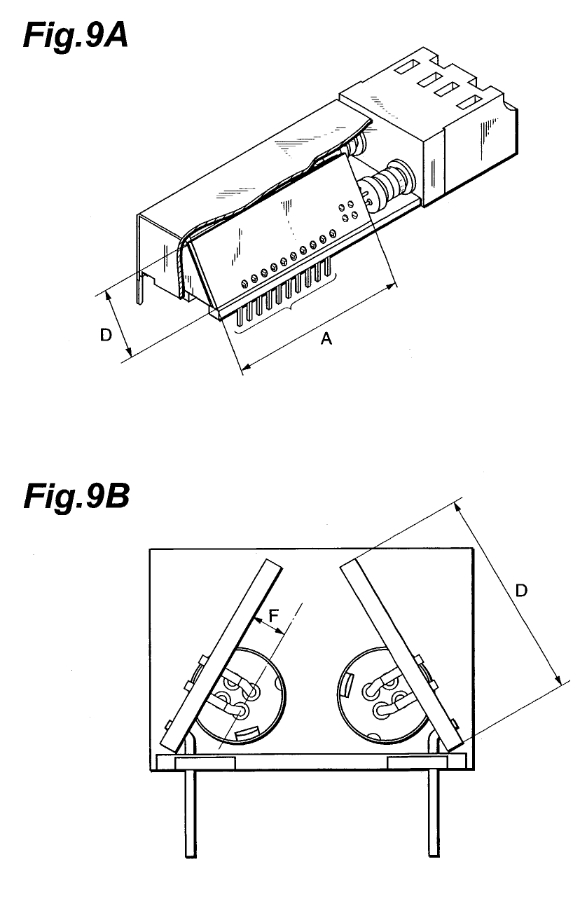

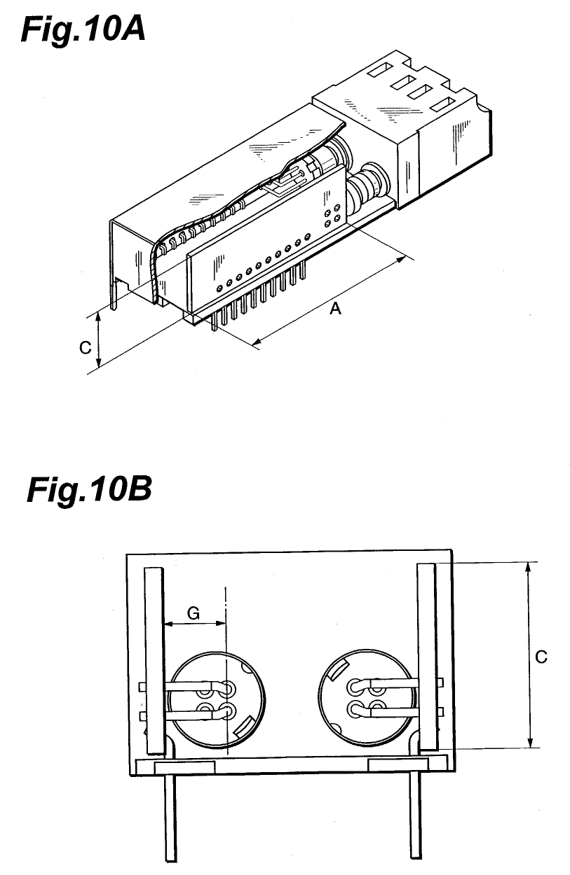

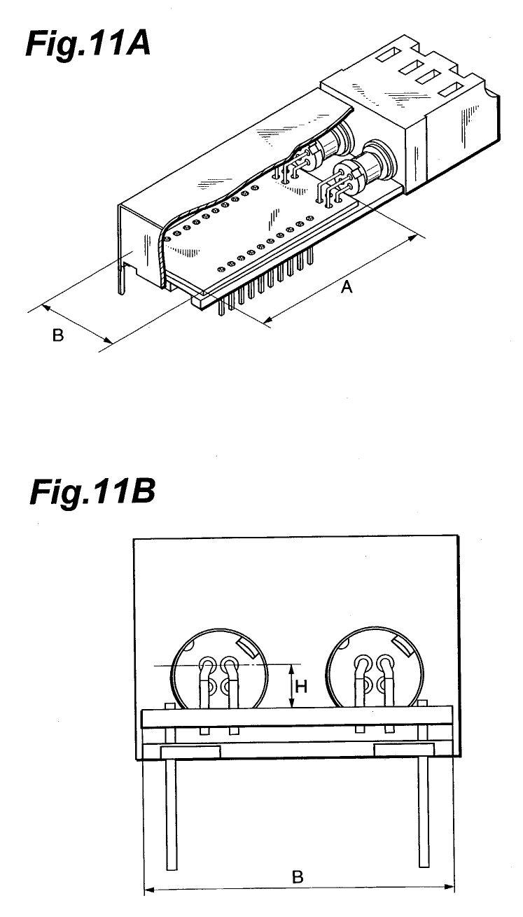

FIGS. 9A, 9B, 10A, 10B, 11A and 11B show how the areas of the wiring substrates are increased by the present embodiment. It is assumed that each of the optical data links illustrated in these drawings has the same size of the housing as the others. In the optical data link shown in FIGS. 9A and 9B, the wiring substrates are inclined with respect to the base portion. In this example, the size of a wiring substrate is denoted by symbols A and D. In the optical data link of the comparative example shown in FIGS. 10A and 10B, the wiring substrates are disposed so as to be perpendicular to the base portion. In this example, the size of a wiring substrate is denoted by symbols A and C. In the optical data link of the comparative example shown in FIGS. 11A and 11B, a wiring substrate is disposed so as to be parallel to the base portion. In this example, the size of a wiring substrate is denoted by symbols A and C. In the comparative examples, the areas of the wiring substrates are increased because of the inclination of the substrates.

In the optical data link shown in FIGS. 9A and 9B, because of disposing the wiring substrates in an inclined fashion, it is possible to obtain a component mounting face whose area is larger than the area of the wiring substrates of the optical data links shown in FIG. 10A to FIG. 11B. Furthermore, it also becomes possible to reduce the length F of the lead terminals of the subassemblies in comparison with the lengths G and H of the lead terminals of the optical data links shown in FIG. 10A to FIG. 11B. In addition, not only is it possible to make the receiving circuit board for the receiver and the transmitting circuit board for the transmitter separate to each other, but also the receiving circuit board and the transmitting circuit board may be disposed so as to be inclined from each other, thereby improving cross-talk in the optical data link in comparison with optical data links in which the receiving circuit board and the transmitting circuit board are disposed in parallel (as shown in FIGS. 10A to 11B).

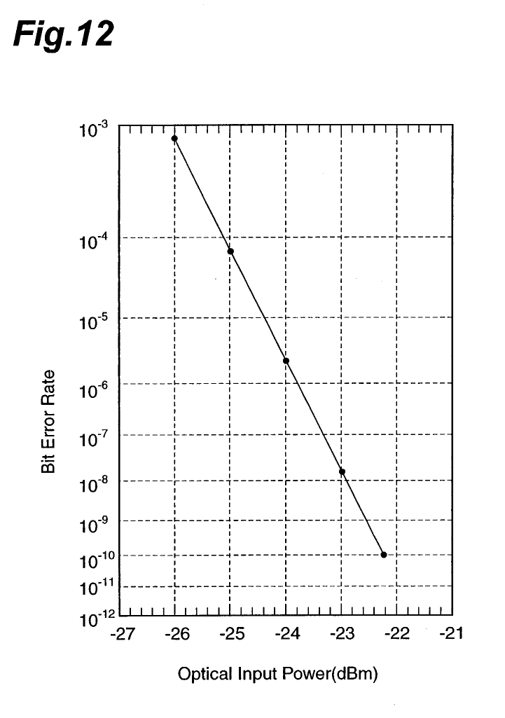

FIG. 12 shows the bit error rate characteristic of an optical data link shown in the embodiment. The horizontal axis represents optical input power (dBm), and the vertical axis represents the bit error rate. According to the test results, as the optical input power increases, the bit rate error drops as far as 10⁻¹⁰. This result reveals an improvement of the noise characteristics. In the optical data link, each of the two substrates is inclined at an angle of π/3 radian, and the angle formed by the two substrates is 2π/3 radian. In order to improve the noise margin, the angle formed by the wiring substrate 18 and the wiring substrate 22 may be not less than 20 degrees and not more than 160 degrees.

(Second embodiment)

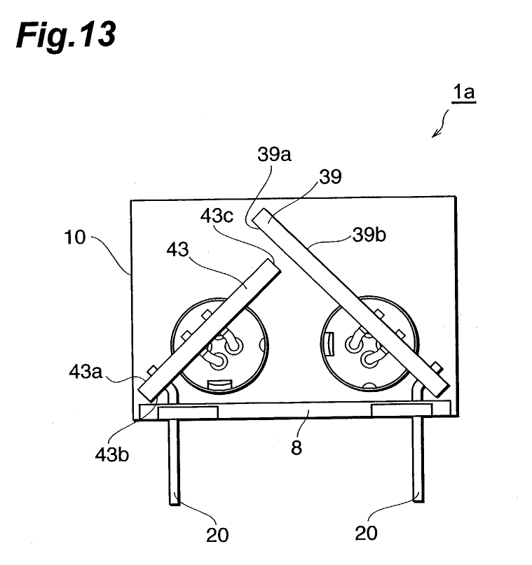

FIG. 13 shows an optical data link according to another embodiment. In the optical data link 1a of this embodiment, the size of one circuit board 39 is larger than the size of the other circuit board 43. The edge 43c of the wiring substrate 43 faces a component mounting face 39a of the wiring substrate 39. This embodiment is suitable for an optical data link where the number of the circuit components required for a transmitter is different from that for a receiver. Not only is it possible to dispose the circuit boards symmetrically as in the first embodiment, but it is also possible to dispose the circuit boards asymmetrically as in the present embodiment. It is also possible, in the present embodiment, to mount an electronic element not only on the component mounting face 39a of the wiring substrate 39, but also on the opposite side 39b. Furthermore, it is also possible to mount an electronic element not only on the component mounting face 43a of the wiring substrate 43, but also on the opposite side 43b. In the optical data link 1a, the wiring substrate 43 extends in a direction of one reference plane, the wiring substrate 39 extends in a direction of another reference plane, and the reference plane intersects the wiring substrate 39. The other reference plane may intersect the wiring substrate 43.

(Third embodiment)

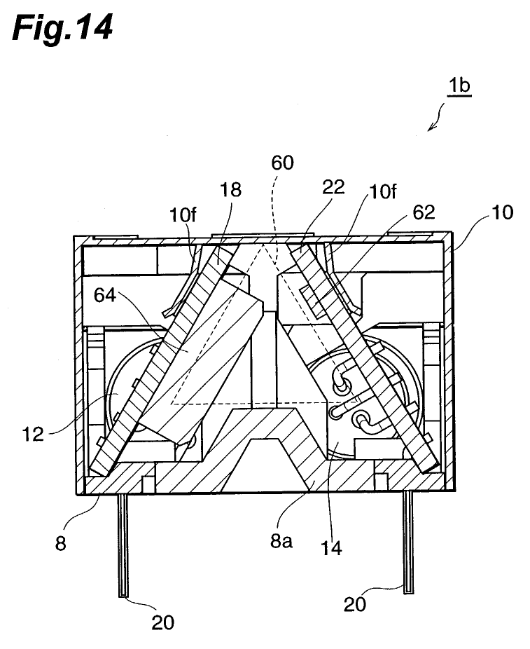

FIG. 14 shows an optical data link according to another embodiment. Referring to FIG. 14, in the optical data link 1b, the wiring substrate 18 is provided so as to face one side face of a reference triangle pole 60 extending in a predetermined axial direction, and the wiring substrate 22 is provided so as to face another side face of the reference triangle pole 60. The base portion 8a of the mounting member 8 is provided so as to face yet another side face of the reference triangle pole. An electronic component and another electronic component are disposed in an electronic component disposition space provided between the wiring substrates 18 and 22. The electronic component disposition space is shared by the wiring substrates 18 and 22. Consequently, when an electronic component 64 is mounted on the wiring substrate 18 and another electronic component 62 is mounted on the wiring substrate 22, the large electronic component 64 can occupy most of the electronic component disposition space.

(Fourth embodiment)

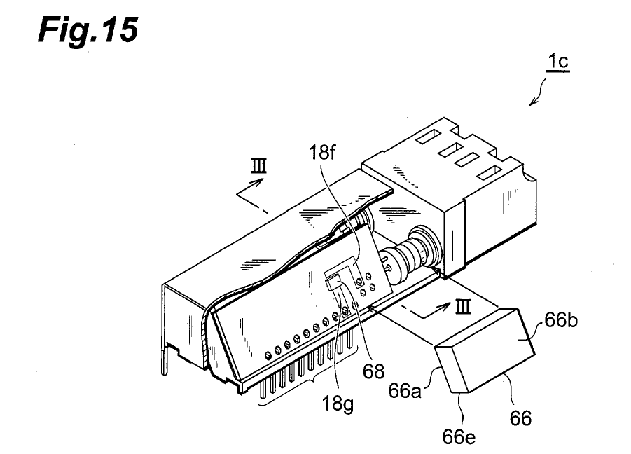

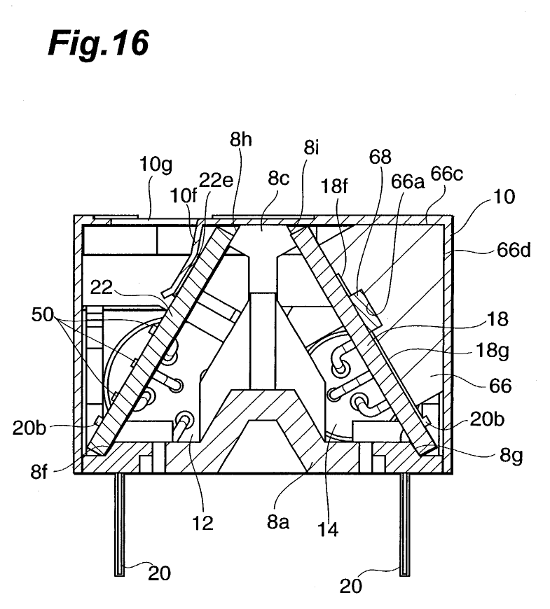

FIG. 15 is a perspective view of an optical data link according to another embodiment. FIG. 16 is a cross-sectional view taken along the line III-III in FIG. 15. Referring to FIGS. 15 and 16, the optical data link 1c may further comprise a heat transfer part 66. The heat transfer part 66 has a rectangular parallelepiped shape, as illustrated in FIG. 15 before the heat transfer part 66 is housed in the optical data link 1c. But the shape of the heat transfer part 66 deforms in accordance with the shape of a region within the optical data link 1c when the heat transfer part 66 is disposed between the cover member 10 and the substrate 18, and the cover member 10 and the photoelectric conversion device 14, as shown in FIG. 16.

The heat transfer part 66 is positioned between the circuit board 18 and the cover member 10. An electronic element 68 is disposed below the heat transfer part 66. When the heat transfer part 66 is disposed on the circuit board 18, the heat transfer part 66 contacts the electronic element 68 and the electrical conduction part of the photoelectric conversion device 14, and contacts the interior of the cover member 10. To implement this contact, the heat transfer part 66 has a number of surfaces. One of these surfaces, a surface 66a, has a size sufficient to cover both the electronic element 68 and the photoelectric conversion device 14. The surface 60b deforms in contact with the inner walls of the cover member 10 to form surfaces 66c and 66d. The heat transfer part 66 serves to transfer heat from the electronic element 68 and photoelectric conversion device 14 to the cover member 10, and functions as a heat transfer member. Also the heat transfer part 66 has a side surface 66e, which is different from the surfaces 66a, 66c and 66d, and heat can be dissipated from these side surfaces into the air. In a preferred embodiment, the photoelectric conversion device 14 is an optical transmitter subassembly having a semiconductor light emitting element, and the electronic element 66 can be a semiconductor driving element for driving the semiconductor light emitting element.

The heat transfer part 66 has a thickness similar to or slightly larger than the space between the circuit board 18 and the cover member 10. Also the heat transfer part 66 preferably exhibits flexibility capable of deforming in accordance with the shape of the electronic element 68 and the electrically conduction pin 25g of the optical data link 25 when the heat transfer part 66 is disposed between the cover member 10 and the electronic element 68 and optical data link 25.

Because of this nature of the heat transfer part 66, the following advantages are provided. The contact between the heat transfer part 66 and the electronic element 68 and optical data link 25 becomes reliable by stress from the compressed heat transfer part 66, and the contact area between the heat transfer part 66 and the electronic element 68 and optical data link 25 can be increased by the deformation of the heat transfer part 66. Since the heat transfer part 66 deforms in accordance with the outer shape of the electronic element 68 and optical data link 25 making contact therewith, it is unnecessary to form the heat transfer part 66 to be a desired shape. In addition, the heat transfer part 66 has an electrical insulation property so that electrical conduction does not occur between the photoelectric conversion device 14 and the cover member 10 via the heat transfer part.

Heat from the electronic element 68 and the photoelectric conversion device 14 diffuses and spreads in the heat transfer part 66. The contact area between the heat transfer part 66 and the cover element 10 is large in comparison with the contact area between the heat transfer part 66 and the electronic element 68 and photoelectric conversion device 14. Since this heat is transferred to the cover member 10 via the larger contact face, the heat radiation becomes efficient.

By the deformation of the heat transfer part 66, the adhesion between the electronic element 68 and photoelectric conversion device 14 and the heat transfer part 66 is improved. It is preferable that the heat transfer part 66 is made of material exhibiting good adhesion property, and this property makes it easier to maintain adhesive contact between the heat transfer part 66 and parts to be contacted.

The inventor thinks as follows: The characteristic of the material for the heat transfer part 66 preferably has a thermal conductivity of 2.0 W/m·K or more. An example of the material of the heat transfer part 66 is silicone gel material.

Referring to FIG. 15, wiring layers 18f and 18g are provided on the wiring substrate 18, and are connected with the electronic element 68. The heat transfer part 66 preferably contacts at least one of the wiring layers 18f and 18g. The contact between the heat transfer part 66 and the wiring layers 18f and 18g permits heat transfer part 66 to receive heat from the electronic element 68 via these wiring layers. The wiring layer 18f on the wiring substrate 18 is connected with the photoelectric conversion device 14 and the electronic element 68. The contact between the heat transfer part 66 and the wiring layer 18f permits the heat transfer part 66 to receive heat from both the photoelectric conversion device 14 and the electronic element 68 via the wiring layer 18f. The contact can reduce the mutual thermal interference between the photoelectric conversion device 14 and the electronic element 68.

In the optical data link 1c, the heat transfer part 66 is disposed so as to contact the top and side surfaces of the electronic element 68. The heat transfer part 66 is positioned so as to contact the electrical conduction member, such as the wiring layers 18f and 18g connected with the electronic element 68, and so as to cover the electronic element 68. In addition, the heat transfer part 66 is positioned so as to contact the electrically conductive member, such as the photoelectric conversion device 14.

(Fifth embodiment)

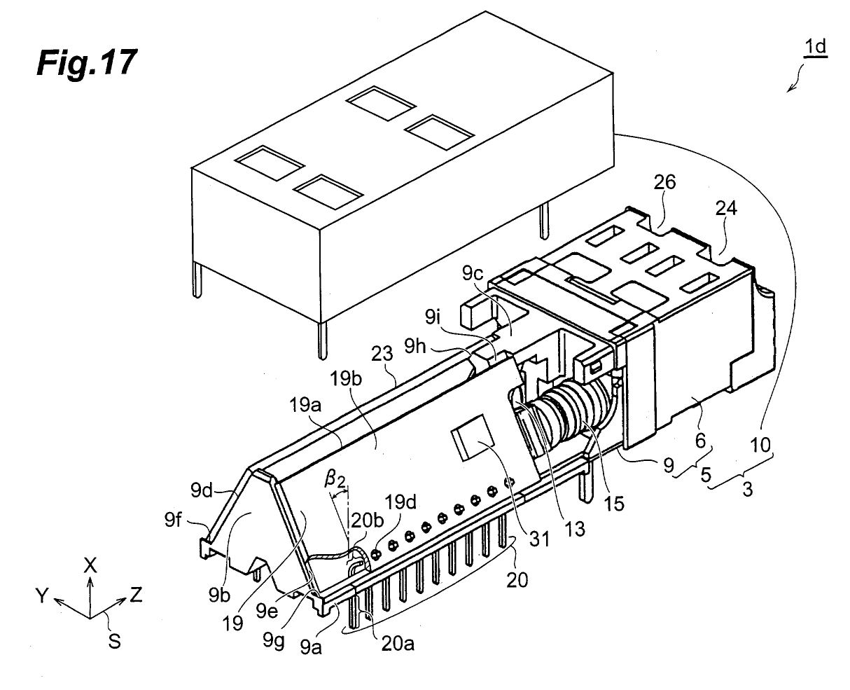

FIG. 17 is a view showing an optical data link according to an embodiment of the present invention. The optical data link id comprises a housing 3, a first photoelectric conversion device 13 and second photoelectric conversion device 15. The housing 3 may include a housing member 5 having a mounting member 9 and a receptacle member 6. The housing member 5 supports the first and second photoelectric conversion device 13 and 15. The receptacle member 6 is provided with receptacles 24 and 26, and the receptacles 24 and 26 extend in a prescribed axial direction. The housing member 5 has a mounting member 9 and a cover member 10. The mounting member 9 mounts the substrates 19 and 23 for the photoelectric conversion devices 12 and 14 thereon. The cover member 10 is disposed on the mounting member 9, and the photoelectric conversion devices 12 and 14 and the substrates 19 and 23 are positioned between the cover member 10 and the mounting member 9. The structures the photoelectric conversion devices 13 and 15 can be the same as those of the photoelectric conversion devices 12 and 14, respectively, except for the shape of the lead terminals, but is not limited thereto.

The housing 3 can include a receptacle member 6, a mounting member 9, and a cover member 10. As is the case with the housing 2, the housing 3 provides a housing space accommodating the photoelectric conversion devices 13 and 15 and the substrates 19 and 23 so as to be optically coupled to an optical connector.

The mounting member 9 has substantially the same structure as that of the mounting member 8. However, the mounting member 9 has a shape different from the structure of the mounting member 8 in some respects, and is referred as to another reference numeral. Now the mounting member 9 will be described in brief. The mounting member 9 has a base portion 9a and a rear wall portion 9b. The base portion 9a extends in a direction of a prescribed reference plane. The rear wall portion 9b is provided on one edge of the base portion 9a, and extends in a direction intersecting the reference plane. The photoelectric conversion devices 13 and 15 are disposed on the base portion 9a.

The base portion 9a has a series of lead terminals 20 to permit the electrical connection of the photoelectric conversion devices 12 and 14 therewith. The lead terminals 20 are provided on the bottom face of the base portion 9a, and the base portion 9a faces the mounting substrates (not shown in the figure). The lead terminals 20 are bent in a predetermined position from the mounting face of the base portion. The lead terminals 20 are arranged to form a pair of rows of lead terminals in the direction in which the substrates 19 and 23 are provided. The material used for the mounting member 9 is preferably composed of synthetic resin material, such as a liquid crystal polymer, just like the mounting member 8.

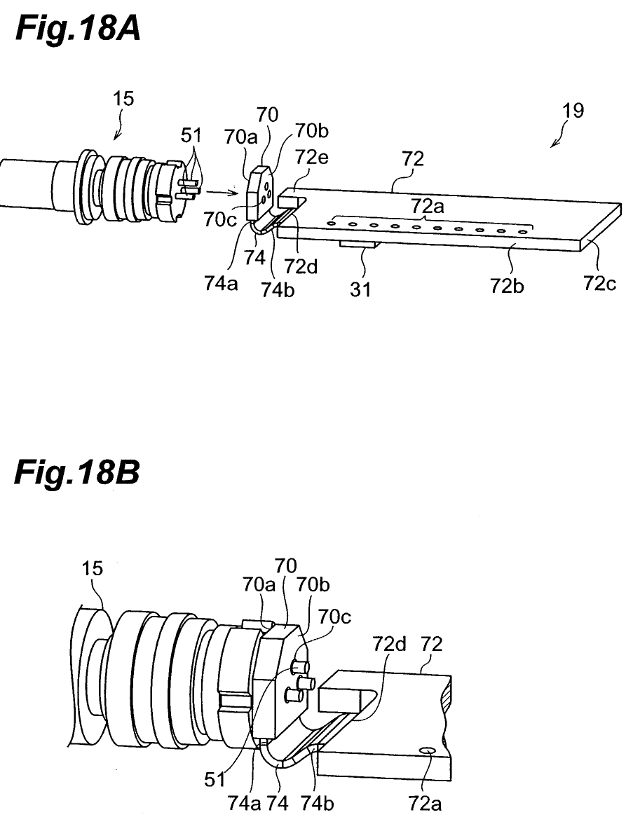

FIGS. 18A and 18B are views each showing an optical communication subassembly and a substrate in an optical data link. In the description herein below, the substrate 19 will be described as an example, but the substrate 23 also has a similar configuration. Referring to FIGS. 18A and 18B, in the optical data link 1d, the photoelectric conversion device 15, such as an optical communication subassembly, is connected with the substrate 19. The substrate 19 has a connection substrate 70 provided on the photoelectric conversion device 15, a circuit board 72 mounting the electronic element 31 thereon, and a flexible printed circuit board 74 connecting the circuit board 72 and the connection substrate 70 with each other. The connection substrate 70 and the circuit board 72 are rigid substrates, which are harder than the flexible printed circuit board 74. The base material of the flexible printed circuit board 74 is polyimide, for example, and the base material of the connection substrate 70 and the circuit board 72 is epoxy and ceramic, for example. That is, the substrate 19 constitutes the flex-rigid substrate.

Using the flexible printed circuit board 74 reduces the restrictions on the arrangement of the photoelectric conversion device 15 and the circuit board 72. For example, even if there is a positional displacement between the photoelectric conversion device 15 and the substrate 19 in the housing 3 in the assembly of the optical data link, the displacement of one of the photoelectric conversion device 15 and the substrate 19 does not cause the displacement of the other one because of the deformation of the flexible printed circuit board 74. Also, even if the position of the photoelectric conversion device 15 and/or substrate 19 displaces due to thermal expansion which may occur during the operation of the optical data link, the displacement of one of the photoelectric conversion device 15 and the substrate 19 does not cause the displacement of the other one of the photoelectric conversion device 15 and the substrate 19. Therefore, the flexible printed circuit board 74 serves to increase the tolerance on displacement between the circuit board 72, which is secured to the lead terminals 20, and the photoelectric conversion device 15, which is secured to the housing 3.

The connection substrate 70 comprises a pair of faces 70a and 70b and through holes 70c which extend from one of the pair of faces to the other. The lead terminals 51 of the photoelectric conversion device 15 are inserted in the through holes 70c. The edge of the connection substrate 70 is connected with one end 74a of the flexible printed circuit board 74. Since the connection substrate 70 is directly attached to the element mounting member of the photoelectric conversion device 15, the length of the lead terminals 51 of the photoelectric conversion device 15 can be reduced. Therefore, the length of the lead terminals 51, the impedance of which cannot be set to a desired value, can be reduced. Also, lead forming is not needed for the photoelectric conversion device 15.

The circuit board 72 mounts electronic element 31 thereon. On the circuit board 72, terminal holes 72a are arranged along one edge 72b which extends in the optical axis direction of the photoelectric conversion device 15. In these terminal holes 72a, the lead terminals 20 of the mounting member 9 are inserted. The circuit board 72 has a pair of edges 72c and 72d which extend in a direction intersecting the optical axis of the photoelectric conversion device 15. One edge 72c is supported by the support face 9d of the side edge of the wall portion 9 of the mounting member 9. The other edge 72d is connected with the other end 74b of the flexible printed circuit board 74. The other edge 72d has a extension 72e which forms an opening provided so as to receive the connection substrate 70 therein when the flexible printed circuit board 74 is flexed.

Referring to FIG. 17 again, in the optical data link id, the substrates 19 and 23 are not disposed in parallel, but the substrates 19 and 23 are disposed so as to be inclined with respect to the reference plane along which the base portion 9a extends. In order to support the substrates in such a inclination fashion, the mounting member 9 has support faces 9d and 9e on the side edge of the wall portion 9b, support faces 9f and 9g on opposite edges of the base portion 9a, and support faces (guide faces) 9h and 9i on both edges of the support portion 9c. The support faces 9d and 9e are provided so as to support the wiring substrates 19 and 23 around the edges thereof. The support faces 9f and 9g are provided so as to support the wiring substrates 19 and 22 around the lower edges thereof. The support faces 9h and 9i are provided so as to support the wiring substrates 19 and 23 around the upper edges thereof. These faces work as guide faces. These guide faces serve to prevent the wiring substrates 19 and 23 from moving to an unexpected position in mounting the wiring substrates 19 and 23 in the housing 3. The guide faces also serve to prevent the substrates 19 and 23 from being disposed at an unexpected position within the housing 3.

The substrates 19 and 23 are disposed so as to be inclined at an angle α₁ with respect to the housing 3, as is the case with the wiring substrates 18 and 22 shown in FIG. 4. In the description herein below, the substrate 19 will be described as an example. The angle α₁ is greater than zero radian and smaller than π/2 radian. The lead terminals 20 for the wiring substrate 19 have a structure similar to the lead terminals shown in FIG. 4. In other words, the lead terminals 20 have a first portion 20a and a second portion 20b, and the second portion 20b is inclined at an angle β₁ (radian) with respect to the reference plane (shown by the dashed line 32a in FIG. 4). The second portion 20b of the lead terminals 20 is inserted into holes 19d of the wiring substrate 19.

In the optical data link 1c shown in FIG. 17, the wiring substrates 19 and 23 are disposed so as to be inclined with respect to the reference plane along which the base portion 9a extends. In the preferred embodiment, the angle formed by the substrate 19 and the reference plane is not less than 10 degrees and not more than 80 degrees. The angle formed by the wiring substrate 23 and the reference plane is not less than 10 degrees and not more than 80 degrees.

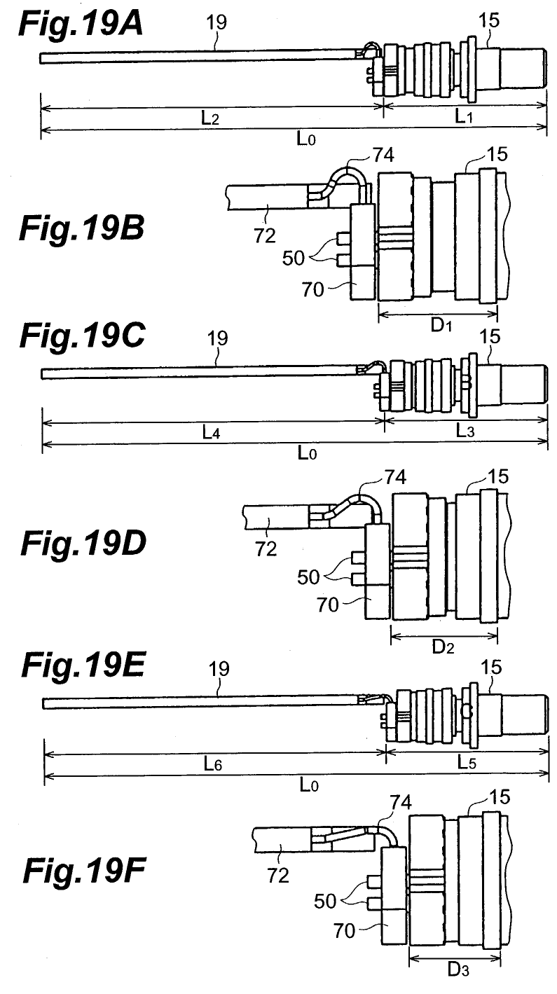

FIGS. 19A to 19F are views showing the relationship exhibiting various alignments with respect to the Z axis between the photoelectric conversion device 15 and the substrate 19. The Z axis is defined by the coordinate system as shown in FIG. 17. Alignments with respect to the Z axis change variably depending on the position of the photoelectric conversion device 15 which is adjusted so as to obtain desired performance. In order to house the photoelectric conversion device 15 and the substrate 19 aligned with each other in the housing 3, it is demanded that the total length of the aligned photoelectric conversion device 15 and the substrate 19 become L₀.

In the optical data link shown in FIG. 19A and FIG. 19B, the photoelectric conversion device 15 has its length of L₁ after the photoelectric conversion device 15 has been aligned. In the optical data link shown in FIG. 19C and FIG. 19D, the photoelectric conversion device 15 has its length of L₃ after the photoelectric conversion device 15 has been aligned. In the optical data link shown in FIG. 19E and FIG. 19F, the photoelectric conversion device 15 has its length of L₅ after the photoelectric conversion device 15 has been aligned. The lengths of these photoelectric conversion devices 15 satisfies the relationship: L₅<L₃<L₁.

Referring to FIG. 19A, the degree of flexion of the flexible printed circuit board 74 is relatively large, and the substrate 19 has the length L₂ by this flexion. As a result, the total length of the photoelectric conversion device 15 and the substrate 19 becomes a desired value L₀. Referring to FIG. 19C, the degree of flexion of the flexible printed circuit board 74 is relatively moderate, and the substrate 19 has the length L₄ by this flexion. As a result, the total length of the photoelectric conversion device 15 and the substrate 19 becomes a desired value L₀. Also referring to FIG. 19E, the degree of flexion of the flexible printed circuit board 74 is relatively large, and the substrate 19 has the length L₆ by this flexion. As a result, the total length of the photoelectric conversion device 15 and the substrate 19 has a desired value L₀. Therefore, the total length of these substrates 19 satisfies the relationship L₂<L₄<L₆.

As shown in FIGS. 19B, 19D and FIG. 19F, the total length of the photoelectric conversion device satisfies the relationship, D₁>D₂>D₃, as a result of the alignment of the photoelectric conversion device 15. However, in the photoelectric conversion device 15, an individual length of the photoelectric conversion device 15 depends on the axial alignment. Although the length of the photoelectric conversion device 15 is individually different due to the alignment, the flexible printed circuit board can connect the photoelectric conversion device 15 and the circuit board with each other to form a connected assembly, and this connected assembly can be housed in the housing 3 with the predetermined dimension.

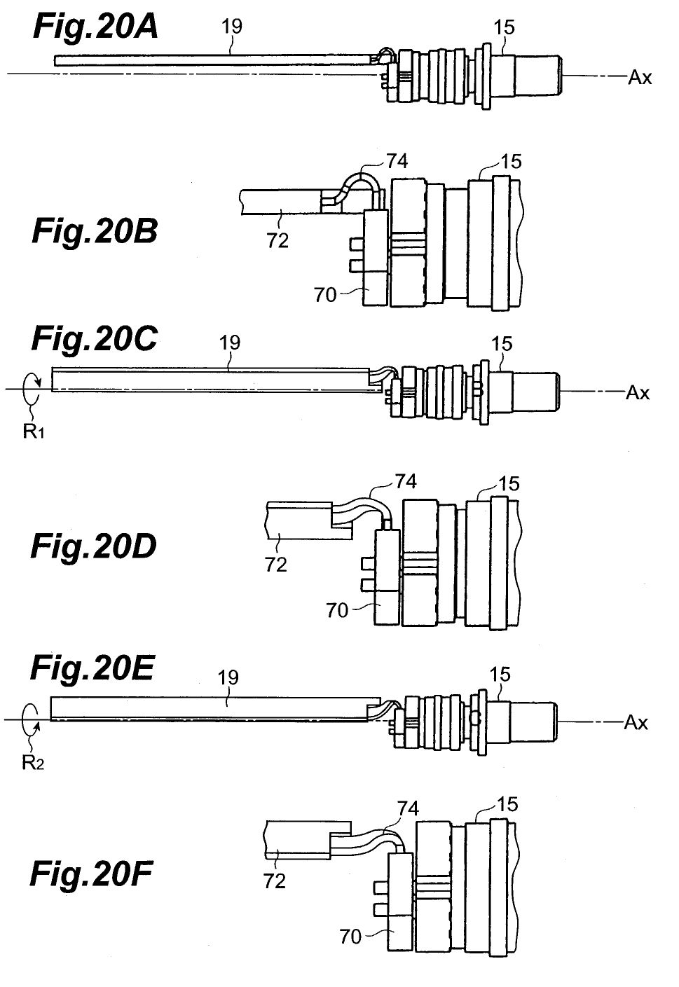

FIGS. 20A to 20F are views showing the arrangements of the photoelectric conversion device 15 and the substrate 19 in the housing 3. In FIGS. 20A, 20C and 20E, the central axis Ax, which is positioned on the optical axis of the photoelectric conversion device 15, is indicated by a dashed line.

In the optical data link shown in FIGS. 20A and 20B, the photoelectric conversion device 15 and the circuit board 72 are disposed in the housing 3 such that the torsion of the flexible printed circuit board 74 substantially does not occur. In the optical data link shown in FIGS. 20C and 20D, the circuit board 72 relatively rotates in the direction indicated by arrow R₁ with respect to the photoelectric conversion device 15 when the photoelectric conversion device 15 and the circuit board 72 are disposed in the housing 3, and the flexible printed circuit board 74 is twisted. In the optical data link shown in FIGS. 20E and 20F, the circuit board 72 relatively rotates in the direction indicated by arrow R₂ with respect to the photoelectric conversion device 15 when the photoelectric conversion device 15 and the circuit board 72 are disposed in the housing 3, and the flexible printed circuit board 74 is twisted.

FIGS. 20A to 20F show a number of arrangements of the photoelectric conversion device 15 and the circuit board 72, but the difference in arrangements is tolerated in the housing 3 because of the flexible printed circuit board twisting in a required amount and in a required direction.

As is the case with the wiring substrates 18 and 22 of the first embodiment, the substrates 19 and 23 can have a thermal via formed from metal in the insulation layer. The optical data link 1d can acquire its functions and technical advantages of the thermal via similar to those of the optical data link 1.

(Sixth embodiment)

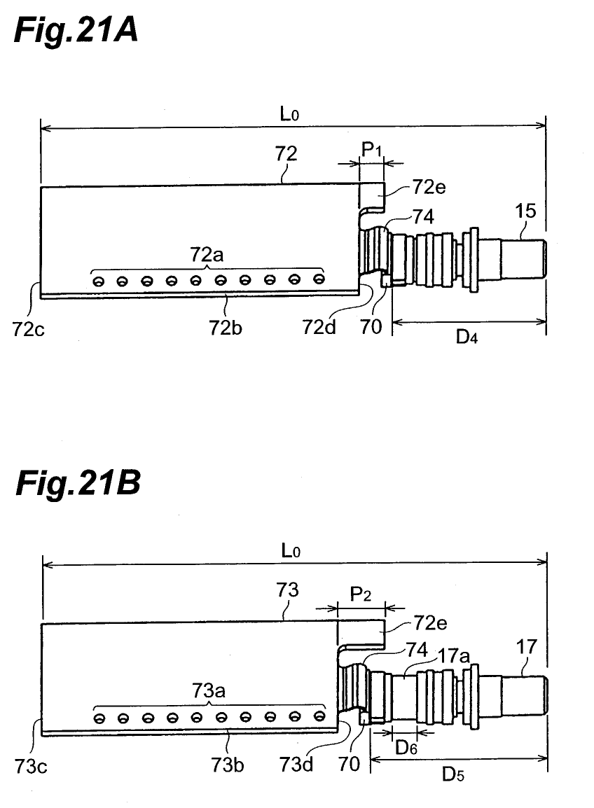

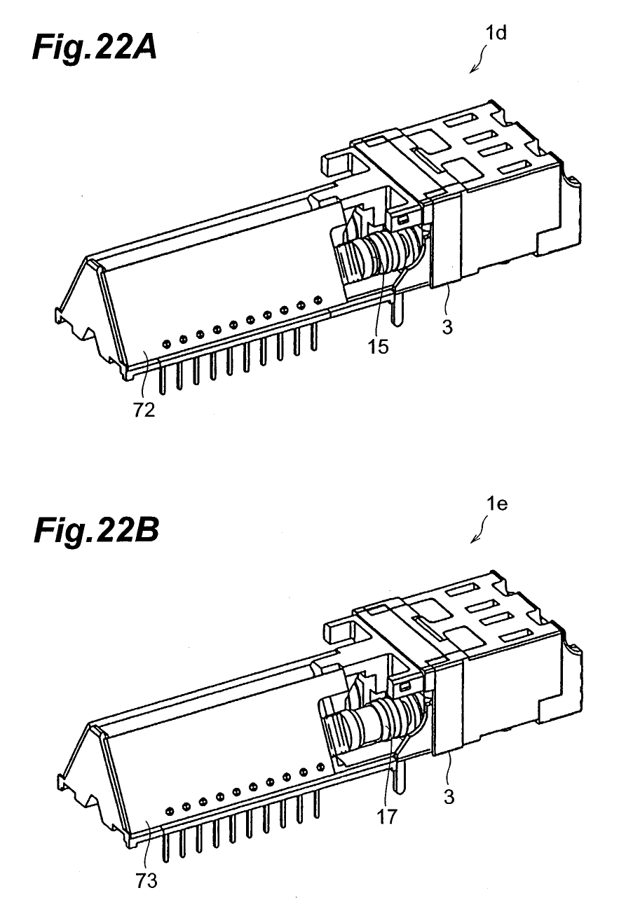

FIG. 21A is a view showing a substrate and a photoelectric conversion device which does not have an optical isolator, and FIG. 21B is a view showing a substrate and a photoelectric conversion device which has an optical isolator. FIG. 22A is a view showing an optical data link comprising a substrate and a photoelectric conversion device which does not have an optical isolator, and FIG. 22B is a view showing an optical data link comprising a substrate and a photoelectric conversion device which has an optical isolator.

In the optical data link 1d in FIG. 21A, the total length of the photoelectric conversion device is length D₄. In the optical data link le in FIG. 21B, the photoelectric conversion device 17 is produced by adding an optical isolator to the photoelectric conversion device 15, and the total length thereof becomes length D₅. In the photoelectric conversion device 17, the total length of the photoelectric conversion device 17 is D₅=D₄+D₆.

As shown in FIG. 21B, the optical data link le has a circuit board 73 in place of the circuit board 72. In the circuit board 73, the protrusion 73e is provided at the edge 73d to which the flexible printed circuit board 74 is connected, and the length P₂ of the protrusion 73e is longer than the length P₁ of the protrusion 72e of the circuit board 72 by the length of an optical isolator. The distance between the edge 73c and the edge 73d in the circuit board 73 is shorter than that of the circuit board 72 by the amount of this value of the optical isolator. Consequently, the total length of the photoelectric conversion device 15 and the substrate 19 shown in FIG. 21B can be set to a desired value L₀, which is the same as the total length of the photoelectric conversion device 15 and the substrate 19 shown in FIG. 21A. The distance of the plurality of holes 73a from the edge 73c is the same as the distance of the plurality of holes 72a from the edge 72c. Therefore, as shown in FIGS. 22A and 22B, the size of a housing for the optical data link 1d comprising a substrate and a photoelectric conversion device with an optical isolator can be the same as that for the optical data link le comprising a substrate and a photoelectric conversion device without an optical isolator.

(Seventh embodiment)

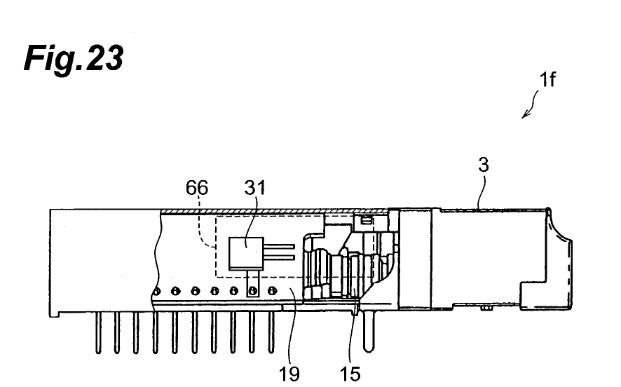

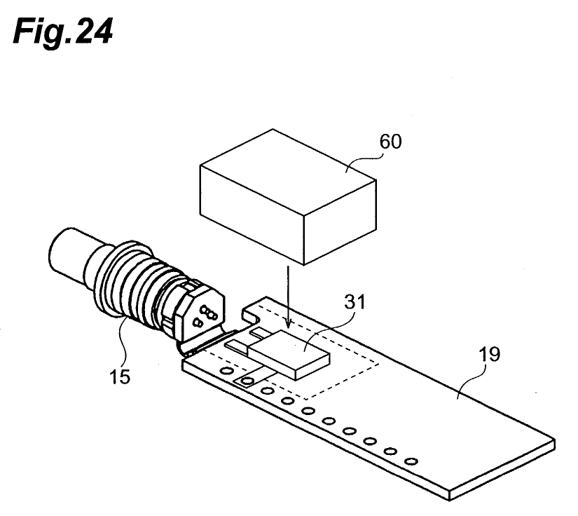

FIG. 23 is a perspective view showing an optical data link according to another embodiment. FIG. 24 is a view showing the arrangement of a substrate, a photoelectric conversion device, and a heat transfer part. Referring to FIGS. 23 and 24, the optical data link 1f further comprises a heat transfer part 66. The heat transfer part 66 is provided between a cover member 10 and a substrate 19, and between a cover member 10 and a photoelectric conversion device 15. The use of the heat transfer part 66 provides the optical data link 1f with the functions and technical advantages of the heat transfer part 66 in the optical data link 1.

The heat transfer part 66 is positioned between the circuit board 18 and the cover member 10. An electronic element 31 is disposed under the heat transfer part 66. When the heat transfer part 66 is disposed on the circuit board 19, the heat transfer part 66 makes contact with the electrical conductive portion of the photoelectric conversion device 15, the electronic element 31 and the rigid circuit board 72, and makes contact with the cover member 10. The heat transfer part 66 serves to transfer heat from the electronic element 68 and the photoelectric conversion device 15 to the cover member 10, and works as a thermal transfer medium. In a preferred example, the photoelectric conversion device 15 is an optical transmitter subassembly including a semiconductor light emitting element, and the electronic element 31 is a semiconductor driving element for driving the semiconductor light emitting element. Both the semiconductor light emitting element and semiconductor driving element generates a large amount of heat during operation. Heat radiation by the heat transfer part 66 can decrease the temperatures of the semiconductor light emitting element and semiconductor driving element during operation.

The heat transfer part 66 has a thickness similar to or slightly larger than the distance between the circuit board 19 and the cover element 10. Also, the thermal conductivity part 66 preferably has a sufficient softness to deform according to the outer shape of the rigid circuit board 72, electronic element 31 and the electrically conductive pin 25g of the photoelectric conversion device 15 when the heat transfer part 66 is disposed between the cover member 10 and the electronic element 31 and photoelectric conduction device 15. This features of the part 66 provides the following advantages: The contact between the heat transfer part 66 and the electronic element 31 and photoelectric conversion device 15 becomes reliable by the repulsive stress of the compressed thermal conductivity part 66. Also the contact area between the heat transfer part 66 and the electronic element 31 and photoelectric conversion device 15 can be increased because of the deformation of the heat transfer part 66. Furthermore, the heat transfer part 66 deforms according to the outer shape of the electronic element 31 and photoelectric conversion device 15 in contact therewith, so that it is unnecessary to process the heat transfer part 66 to form a desired shape. In addition, the heat transfer part 66 has an electrical insulating property to prevent electrical conduction between the photoelectric conversion device 15 and the cover member 10 via the heat transfer part 66. The heat transfer part 66 preferably exhibits adhesion. Because of this adhesion, maintaining contact between the heat transfer part 66 and a part to be contacted therewith becomes easier.

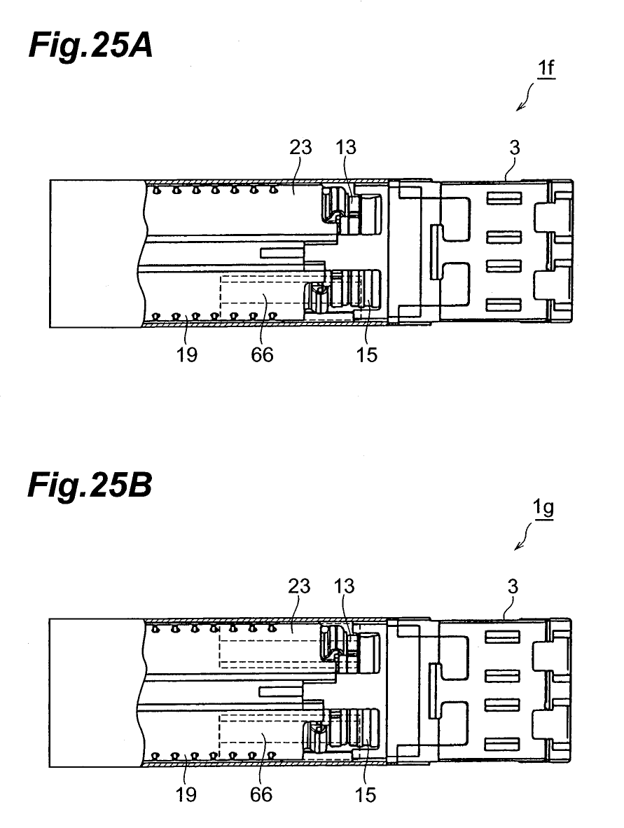

FIG. 25A is a plan view showing the optical data link shown in FIG. 22. FIG. 25B is a plan view showing a modification of the optical data link shown in FIG. 23A. Referring to FIG. 25B, the optical data link 1g may further comprise a substrate 23 and a heat transfer part 67 for the photoelectric conversion device 13, in addition to the heat transfer part 66. The heat transfer part 67 is used to dissipate heat generated in the substrate 23 and the photoelectric conversion device 13. The heat transfer part 67 has characteristics similar to the heat transfer part 66, and in the present embodiment, the heat transfer part 67 has a shape similar to that of the heat transfer part 66.

(Eighth embodiment)

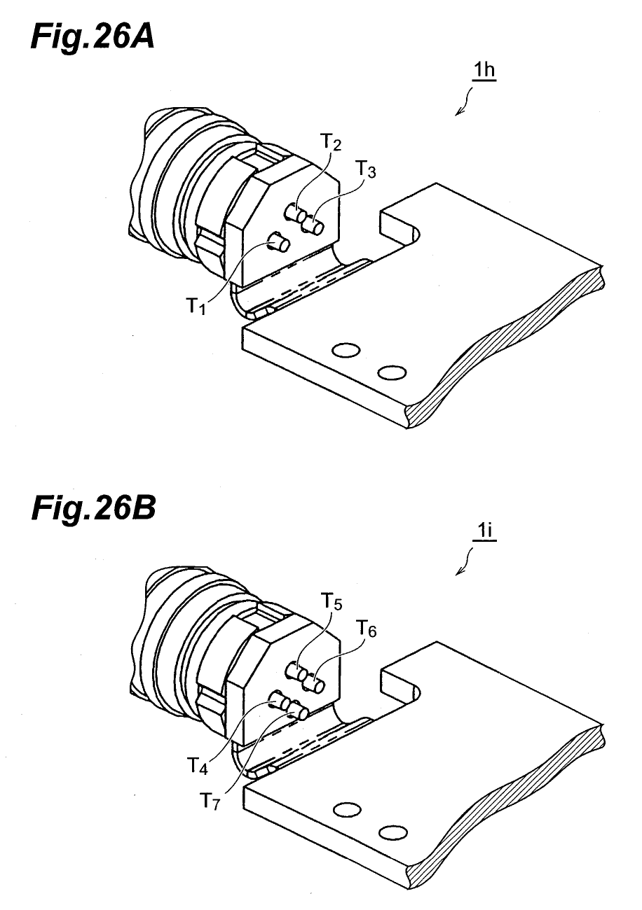

FIG. 26A is a drawing showing an optical data link 1h comprising a photoelectric conversion device having three lead terminals, T₁ to T₃, and a flexible-rigid substrate. FIG. 26B is a drawing showing an optical data link 1i comprising a photoelectric conversion device having four lead terminals, T₄ to T₇, and a flexible-rigid substrate. In the optical data link having a flexible-rigid substrate, the number of its lead terminals can change easily as compared with a lead forming type optical data link.

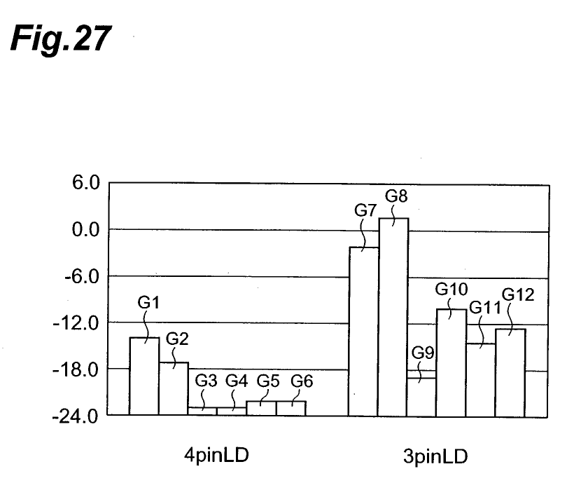

FIG. 27 is a graph showing the noise margin of the optical data links shown in FIGS. 26A and 26B. For the optical data link 1i (four pin LD), the characteristic curves G1 to G6 are shown. The curve G1 shows the noise component in the direction horizontal to the substrate at 1250 MHz. The curve G2 shows the noise component in the direction vertical to the substrate at 1250 MHz. The curve G3 shows the noise component in the direction horizontal to the substrate at 5000 MHz. The curve G4 shows the noise component in the direction vertical to the substrate at 5000 MHz. The curve G5 shows the noise component in the direction horizontal to the substrate at 6250 MHz. The curve G6 shows the noise component in the direction vertical to the substrate at 6250 MHz. For the optical data link 1h (3 pin LD), the characteristic curves G7 to G12 are shown. The curve G7 shows the noise component in the direction horizontal to the substrate at 1250 MHz. The curve G8 shows the noise component in the direction vertical to the substrate at 1250 MHz. The curve G9 shows the noise component in the direction horizontal to the substrate at 5000 MHz. The curve G10 shows the noise component in the direction vertical to the substrate at 5000 MHz. The curve G11 shows the noise component in the direction horizontal to the substrate at 6250 MHz. The curve G12 shows the noise component in the direction vertical to the substrate at 6250 MHz. Referring to FIG. 27, in the optical data link 1i, the potential of the housing can be connected to the GND potential, so that the noise margin of the optical data link 1i is better than that of the optical data link 1h.

(Ninth Embodiment)

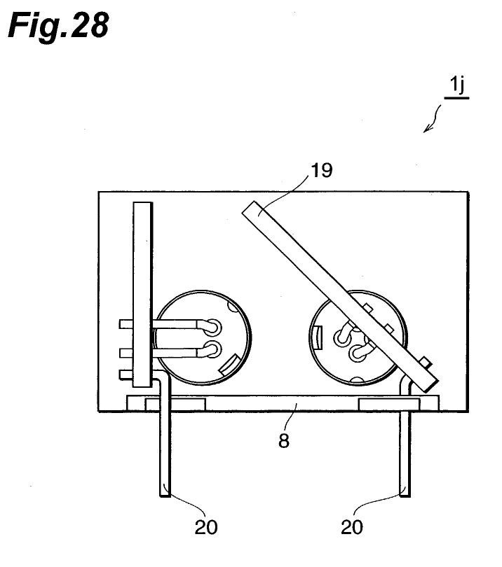

FIG. 28 is a view showing a modification of an optical data link which can be applied to the embodiments described heretofore. The optical data link 1j comprises a housing, first and second photoelectric conversion devices such as optical communication subassemblies, first and second substrates, and electronic components, as shown in the embodiments heretofore. The housing has a base portion extending along the reference plane. The first substrate is disposed so as to be inclined at a first angle with respect to another reference plane orthogonal to the above reference plane. The second substrate, on the other hand, is disposed so as not to be inclined. Since the first substrate is disposed within the housing so as to be inclined, the surface area of the substrate is increased. As a consequence, a larger electronic component or an electronic component with higher function can be mounted.

As described herein above, the wiring substrates are disposed in an inclined fashion in the optical data links according to the present embodiments, so that the areas of the wiring substrates for mounting components may be increased, and a miniature, highly functional optical data link can thus be implemented. An optical data link in which the lead terminals of the optical communication subassemblies are short can be implemented. Furthermore, an optical data link is provided which has a structure permitting the wiring substrate for transmission and the wiring substrate for reception are inclined with each other at an angle (preferably right angle). It is, therefore, possible to improve the noise immunity and to reduce cross-talk.

In the optical data link where a transceiver function is implemented on one wiring substrate, the assembly of the optical data link is easy. But, disadvantageous cross-talk within the wiring substrate tends to be generated. In order to resolve such a disadvantageous tendency, the circuit design is essential. In the optical data link of the other comparative example, a transmission function and a reception function are each implemented by separate wiring substrates. If two circuit boards are employed, the assembly of the optical data link is then relatively complicated, but the problem of cross-talk is resolved.

However, as the miniaturization of optical data links progresses, the wiring substrates must also be made small. On the other hand, there is a need to make optical data links highly functional. However, making optical data links highly functional increase the number of circuit components.

Also, in order to improve immunity to extraneous noise and cross-talk, there is a demand to shorten the wiring distance between wiring substrates and lead pins of subassemblies where small electrical signals flow, and to shorten the wiring distance between wiring substrates and the outer leads. However, according to the standard or specification for optical data links, the positions of subassemblies and the positions of the outer leads of optical data links have been determined. So in the structure of the optical data link of the comparative example, the shortening of the wiring distance is not easy. Communications quality of data signals including relatively high frequencies tends to be sensitive to the effects of noise and cross-talk. In the future design of optical data links, there will be a demand to develop more sophisticated optical data links.

It is possible to efficiently utilize the region within the optical data link of the present embodiment by means of the arrangement of the wiring substrates of the optical data link. For example, the transmission circuit needs a large number of electronic components in comparison with the reception circuit, and the transmission circuit can be provided with a large component mounting area by means of an asymmetric arrangement of the wiring substrates. Furthermore, in the optical data link of the present embodiment, disposing the wiring substrates in an inclined fashion allows the decrease of the distance between the wiring substrates and the lead terminals of the subassemblies and of the distance between the wiring substrates and the outer leads. Consequently, it is possible to provide a structure capable of reducing the inductance from the wiring. Moreover, the substrate for the transmission circuit is disposed so as to be relatively inclined with respect to the substrate for the reception circuit. The inclination at an angle close to a right angle or preferably right angle provides a structure of the optical data link capable of suppressing electromagnetic coupling between these substrates. In the preferred embodiment, this angle is not less than 20 degrees but not more than 160 degrees.

In the optical data links of the embodiments described heretofore, the housing holds the two optical communication subassemblies (or the optical receiver subassembly and the optical transmitter subassembly) so that the interval between the two optical communication subassemblies (or the interval between the optical receiver subassembly and optical transmitter subassembly) becomes a predetermined value. According to the embodiments of the present invention, the optical data link can be constituted to increase the area of the substrates on which electronic components housed in the optical data link are mounted even if a predetermined standard defines the interval between the optical subassemblies. A predetermined standard according to the optical data links of the present embodiment is, for example, the Small Form Factor (SFF) standard. According to this standard, the height of the optical data link is 9.8 mm or less, the width thereof is 13.6 mm or less, and the interval of optical assemblies is 6.25 mm. The interval in an array of lead terminals of the base portion is 15.3 mm or more.

The principles of the present invention have been illustrated and described in the preferred embodiments, but it is apparent to a person skilled in the art that the present invention can be modified in arrangement and detail without departing from such principles. For example, the embodiments have described inclined wiring substrates connected with two subassemblies in the optical data link respectively, but the present invention is not limited thereto. Furthermore, the optical data link may also be constituted so as to include two or more optical receiver subassemblies and two or more optical transmitter subassemblies. We, therefore, claim rights to all variations and modifications coming with the spirit and the scope of claims.

What is claimed is:

1. An optical data link comprising:
a housing having a base portion, said base portion extending along a first reference plane;
first and second optical communication subassemblies provided in said housing;
first and second substrates provided in said housing;
an electronic component electrically connected with said first optical communication subassembly, said electronic component being mounted on said first substrate; and
another electronic component electrically connected with said second optical communication subassembly, said other electronic component being mounted on said second substrate;
wherein said first substrate is provided so as to be inclined at a first angle with respect to another reference plane orthogonal to said first reference plane.

2. The optical data link according to claim 1, wherein said second substrate is inclined at a second angle with respect to said other reference plane.

3. The optical data link according to claim 2, wherein said second angle is not less than 10 degrees and not more than 80 degrees.

4. The optical data link according to claim 3, wherein the base portion of said housing has a first lead terminal connected with said first substrate, and a second lead terminal connected with said second substrate, and
wherein said first lead terminal has a portion bent at an angle not less than 10 degrees and not more than 80 degrees, and said second lead terminal has a portion bent at an angle not less than 10 degrees and not more than 80 degrees.

5. The optical data link according to claim 2, wherein one edge of said first substrate faces one surface of said second substrate.

6. The optical data link according to claim 1,
wherein one of said first and second optical communication subassemblies is an optical receiver subassembly provided to receive light incident in a direction of a predetermined axis; and
wherein the other one of said first and second optical communication subassemblies is an optical transmitter subassembly provided to transmits light in said direction.

7. The optical data link according to claim 6,
wherein said first substrate is provided in said housing along a second reference plane inclined with respect to said first reference plane;
wherein said second substrate is provided in said housing along a third reference plane inclined with respect to said first reference plane; and
wherein said first reference plane extends in a direction from said first optical communication subassembly toward said second optical transmitter subassembly.

8. The optical data link according to claim 7, wherein an angle formed by said second reference plane and said third reference plane is not less than 20 degrees and not more than 160 degrees.

9. The optical data link according to claim 6,
wherein said first substrate is provided so as to face a first side face of a reference triangle pole, said reference triangle pole extending in a direction of said predetermined axis;
wherein said second substrate is provided so as to face a second side face of said reference triangle pole;
wherein said base portion is provided so as to face a third side face of said reference triangle pole; and
wherein said electronic component is provided in an electronic component disposition space provided between said first substrate and said second substrate.

10. The optical data link according to claim 1, wherein said housing portion has a first guide face provided to limit a position of said first substrate, said first guide face being inclined at a first angle with respect to said other reference plane.

11. The optical data link according to claim 1, wherein said first substrate comprises a circuit board mounting said electronic element thereon, a connection substrate connected with said first optical communication subassembly, and a flexible printed circuit board connecting said circuit board and said connection substrate with each other.

12. The optical data link according to claim 1,
wherein said first substrate comprises a circuit board mounting said electronic element thereon, a connection substrate connected with said first optical communication subassembly, and a flexible printed circuit board connecting said circuit board and said connection substrate with each other;
wherein said base portion of said housing comprises a first lead terminal connected with said first substrate;
wherein said first lead terminal is connected to said circuit board of said first substrate; and
wherein said housing supports said first and second optical communication subassemblies.

13. The optical data link according to claim 1, wherein said first substrate comprises a circuit board mounting said electronic element thereon, a connection substrate connected with said first optical communication subassembly, and a flexible printed circuit board connecting said circuit board and said connection substrate with each other;
wherein said first optical communication subassembly comprises a semiconductor optical element and an element mounting member, said element mounting member mounting said semiconductor optical element;
wherein said element mounting member has lead terminals extending in a direction of an optical axis of said semiconductor optical element; and
wherein said connection substrate is provided on said element mounting member so as to be connected with said lead terminals.

14. The optical data link according to claim 1,
wherein said first substrate comprises a circuit board mounting said electronic element thereon, a connection substrate connected with said first optical communication subassembly, and a flexible printed circuit board connecting said circuit board and said connection substrate with each other; and
wherein said first optical communication subassembly includes a semiconductor light emitting element.

15. The optical data link according to claim 1, wherein said first angle is not less than 10 degrees and not more than 80 degrees.

16. The optical data link according to claim 1, wherein said housing holds said first and second optical communication subassemblies such than an interval between said first optical communication subassembly and said second optical communication subassembly is a predetermined value.

17. The optical data link according to claim 1,
wherein said housing further comprises a cover member; and
wherein said first and second substrates are provided between said cover member and said base member;
said optical link further comprising:
a heat transfer member making contact with said first and second optical communication subassemblies, said first and second substrates and said cover member.

18. The optical data link according to claim 1, wherein said electronic components are mounted on both sides of said first substrate.

19. The optical data link according to claim 1, wherein said housing has an electrically conductive cover member covering said first and second substrates, and wherein said electrically conductive cover member has a plurality of finger portions, each finger portion being bent so as to make contact with said first substrate.

20. The optical data link according to claim 1, wherein said housing has a receptacle type structure.

21. The optical data link according to claim 1, wherein said housing has a receptacle member, at least a portion of said receptacle member having electrical conductivity.

22. An optical data link comprising:
a housing including a base portion, said base portion extending along a first reference plane, first and second lead terminals being arranged in said housing, said first lead terminal having first and second portions, said first portion passing through said base portion, said second portion being bent at a predetermined angle with respect to said first portion, said predetermined angle excluding π/2 radian, said second lead terminal having first and second portions, said first portion of said second lead terminal passing through said base portion, and said second portion of said second lead terminal being bent at a predetermined angle with respect to said first portion, said predetermined angle excluding π/2 radian;
a first substrate inclined in association with an inclination of said first lead terminal in said housing, said first substrate being electrically connected with said first lead terminals;
a second substrate inclined in association with an inclination of said second lead terminal in said housing, said second substrate being electrically connected with said second lead terminals;
a first optical communication subassembly provided in said housing, said first optical communication subassembly being electrically connected with said first substrate, said first optical communication subassembly being an optical receiver subassembly;
a second optical communication subassembly provided in said housing, said second optical communication subassembly being electrically connected with said second substrate, said second optical communication subassembly being an optical transmitter subassembly;
an electronic component mounted on said first substrate; and
another electronic component mounted on said second substrate.

23. The optical data link according to claim 22,
wherein said predetermined angle of said first lead terminals is not less than 10 degrees and not more than 80 degrees; and
wherein said predetermined angle of said second lead terminals is not less than 10 degrees and not more than 80 degrees.

24. The optical data link according to claim 22,
wherein said first substrate comprises a circuit board mounting said electronic element thereon, a connection substrate connected with said optical transmitter subassembly, and a flexible printed circuit board connecting said circuit board and said connection substrate with each other; and
wherein said second substrate comprises a circuit board mounting said electronic thereon, a connection substrate connected with said optical receiver subassembly, and a flexible printed circuit board connecting said circuit board and said connection substrate with each other.

25. The optical data link according to claim 22,
wherein said first substrate comprises a circuit board mounting said electronic thereon, a connection substrate connected with said optical transmitter subassembly, and a flexible printed circuit board connecting said circuit board and said connection substrate with each other;
wherein said second substrate comprises a circuit board mounting said electronic thereon, a connection substrate connected with said optical receiver subassembly, and a flexible printed circuit board connecting said circuit board and said connection substrate with each other;
wherein said first lead terminal is connected with said circuit board of said first substrate; and
wherein said second lead terminal is connected with said circuit board of said second substrate.

26. The optical data link according to claim 22,
wherein said first substrate comprises a circuit board mounting said electronic element thereon, a connection substrate connected with said optical transmitter subassembly, and a flexible printed circuit board connecting said circuit board and said connection substrate with each other;
wherein said second substrate comprises a circuit board mounting said electronic element thereon, a connection substrate connected with said optical receiver subassembly, and a flexible printed circuit board connecting said circuit board and said connection substrate with each other;
wherein said optical transmitter subassembly comprises a semiconductor light emitting element and an element mounting member, said element mounting member mounting said semiconductor light emitting element thereon, said element mounting member having lead terminals, said lead terminals extending in a direction of an optical axis of said semiconductor light emitting element;
wherein said connection substrate is provided on said element mounting member, said connection substrate being connected with said lead terminals of said optical transmission subassembly;
wherein said optical receiver subassembly comprises a semiconductor light receiving element and an element mounting member, said element mounting member having lead terminals, said lead terminals extending in a direction of an optical axis of said semiconductor light receiving element, said element mounting member mounting said light receiving element thereon; and
wherein said connection substrate is provided on said element mounting member, said connection substrate being connected with said lead terminals of said optical receiver subassembly.

27. An optical data link comprising:
a housing including a base portion extending along a first reference plane and a wall portion extending along a second reference plane, said second reference plane intersecting said first reference plane on said base portion, said wall portion having a first support face and a second support face, said first support face being inclined at a first angle with respect to said first reference plane, and said second support face being inclined at a second angle with respect to said first reference plane;
a first substrate supported by first support face of said wall portion;
a second substrate supported by the second support face of said wall portion;
a first optical communication subassembly electrically connected with an electronic component mounted on said first substrate, said first optical communication subassembly being included in said housing, and said first optical communication subassembly being an optical receiver subassembly; and
a second optical subassembly electrically connected with an electronic component mounted on said second substrate, said second optical subassembly being included in said housing, said second optical communication subassembly being an optical transmitter subassembly.

28. The optical data link according to claim 27,
wherein said first angle is not less than 10 degrees and not more than 80 degrees; and
wherein said first substrate is inclined at said first angle with reference to said first reference plane.

29. The optical data link according to claim 28,
wherein said first substrate comprises a circuit board mounting said electronic element thereon, a connection substrate connected with said optical transmitter subassembly, and a flexible printed circuit board connecting said circuit board and said connection substrate with each other; and
wherein said second substrate comprises a circuit board mounting said electronic element thereon, a connection substrate connected with said optical receiver subassembly, and a flexible printed circuit board connecting said circuit board and said connection substrate with each other.

30. The optical data link according to claim 27,
wherein said first substrate comprises a circuit board mounting said electronic element thereon, a connection substrate connected with said optical transmitter subassembly, and a flexible printed circuit board connecting said circuit board and said connection substrate with each other;
wherein said second substrate comprises a circuit board mounting said electronic element thereon, a connection substrate connected with said optical receiver subassembly, and a flexible printed circuit board connecting said circuit board and said connection substrate with each other;
wherein said base portion of said housing has a first lead terminal connected to said first substrate and a second lead terminal connected to said second substrate,
wherein said first lead terminal is connected with said circuit board of said first substrate;
wherein said second lead terminal is connected with said circuit board of said second substrate; and
wherein said housing holds said optical receiver subassembly and said optical transmitter subassembly.

31. The optical data link according to claim 27,
wherein said first substrate comprises a circuit board mounting said electronic element thereon, a connection substrate connected with said optical transmitter subassembly, and a flexible printed circuit board connecting said circuit board and said connection substrate with each other;
wherein said second substrate comprises a circuit board mounting said electronic element thereon, a connection substrate connected with said optical receiver subassembly, and a flexible printed circuit board connecting said circuit board and said connection substrate with each other;
wherein said optical transmitter subassembly comprises a semiconductor light emitting element and an element mounting member, said element mounting member mounting said semiconductor light emitting element thereon, said element mounting member having lead terminals, said lead terminals extending in a direction of an optical axis of said semiconductor light emitting element;
wherein said connection substrate is provided on said element mounting member of said optical transmitter subassembly;
wherein said optical receiver subassembly comprises a semiconductor light receiving element and an element mounting member, said element mounting member having lead terminals, said lead terminals extending in a direction of an optical axis of said semiconductor light receiving element, said element mounting member mounting said light receiving element thereon; and
wherein said connection substrate is provided on said element mounting member of said optical receiver subassembly.

32. The optical data link according to claim 27, wherein said housing holds said first and second optical communication subassemblies such that an interval between said first optical communication subassembly and said second optical communication subassembly is a predetermined value.

33. missing

34. The optical data link according to claim 27,
wherein said housing further comprises a cover member; and
wherein said first and second substrates are provided between said cover member and said base member;
said optical link further comprising:
a heat transfer member making contact with said first and second optical communication subassemblies, said first and second substrates and said cover member.

35. An optical data link comprising:
a housing including a base portion having first and second lead terminals, said base portion extending along a first reference plane;
an optical receiver subassembly having a plurality of lead terminals, an end portion of each lead terminal being bent, said end portion of each lead terminal being oriented in a direction represented by a first angle less than π/2 radian and greater than zero radian with respect to said first reference plane, said optical receiver subassembly being housed in said housing;
an optical transmitter subassembly having a plurality of lead terminals, an end portion of each lead terminal being bent, said end portion of each lead terminal being oriented in a direction represented by a first angle less than π/2 radian and greater than zero radian with respect to said first reference plane, said optical transmitter subassembly being housed in said housing;
a first substrate inclined in said housing at an angle associated with said orientation of said lead terminals of said optical receiver subassembly so as to be electrically connected with said lead terminals of said optical receiver subassembly;
a second substrate inclined in said housing at an angle associated with said orientation of said lead terminals of said optical transmitter subassembly so as to be electrically connected with said lead terminals of said optical transmitter subassembly;
an electronic component mounted on said first substrate; and
an electronic component mounted on said second substrate.

36. The optical data link according to claim 35,
wherein said first angle is not less than 10 degrees and not more than 80 degrees; and
wherein said first substrate is inclined at said first angle with respect to said first reference plane.

37. The optical data link according to claim 35, wherein said housing holds said first and second optical communication subassemblies such that an interval of said first and second optical communication subassemblies is a predetermined value.

38. The optical data link according to claim 35,
wherein said housing further comprises a cover member; and
wherein said first and second substrates are provided between said cover member and said base member;
said optical link further comprising a heat transfer member, said heat transfer member making contact with said first and second optical communication subassemblies, said first and second substrates and said cover member.
